(19) United States
(12) Patent Application Publication
(10) Pub. No.: US 2010/0264117 A1
(43) Pub. Date: Oct. 21, 2010

(54) PLASMA PROCESSING SYSTEM AND PLASMA PROCESSING METHOD

(75) Inventors: Tadahiro Ohmi, Sendai-shi (JP); Takaaki Matsuoka, Tokyo (JP)

Correspondence Address: CANTOR COLBURN, LLP, 20 Church Street, 22nd Floor, Hartford, CT, 06103, US

(73) Assignees: TOHOKU UNIVERSITY, Sendai-shi, Miyagi (JP); TOKYO ELECTRON LIMITED, Tokyo (JP)

(21) Appl. No.: 12/740,904

(22) PCT Filed: Oct. 28, 2008
(86) PCT No.: PCT/JP2008/069515

§ 371 Date: May 13, 2010

(30) Foreign Application Priority Data
Oct. 31, 2007 (JP) 2007-284527

(51) Int. Cl. H01L 21/311; C23C 16/50; H01L 21/31; C23C 16/453

(52) U.S. Cl. 216/67; 118/692; 156/345.29; 427/569; 118/621

(57) ABSTRACT

A plasma processing system includes a plasma processing device for forming or etching the plurality of films and a gas source for supplying all gases required for forming or etching the plurality of films. Furthermore, gases required for forming or etching each of the plurality of films are selectively supplied from the gas source to the plasma processing device via gas pipes by a control device. Therefore, a plurality of films of different compositions may be formed or etched within a single plasma processing device.

### TECHNICAL FIELD

The present invention relates to a plasma processing system and a plasma processing method for forming or etching a plurality of films of different compositions.

### BACKGROUND ART

For example, during a manufacturing process in a semiconductor manufacturing device or a liquid crystal display manufacturing device, plasma is generated within a processing chamber by using microwaves, and thus a plasma-processing is performed for forming a film or etching with respect to a substrate.

For such a plasma process, in the case where a plurality of films of different compositions are to be formed or etched, for example, a multi-chamber device, which includes a plurality of process modules arranged around the main transfer chamber for consistency, connectivity, or combination of processes and is also known as a cluster tool, is used conventionally.

For example, a cluster tool for forming and processing a thin-film maintains not only processing vessels of each of process modules, but also the main transfer chamber vacuum, and connects a load-lock module to the main transfer chamber via a gate valve.

A substrate is transferred into the load-lock module at the atmospheric pressure, and then the substrate is extracted from the depressurized load-lock module and is carried into the main transfer chamber. A transferring mechanism installed in the main transfer chamber carries the substrate taken out from the load-lock module into a first process module. The process module performs a first process (e.g. film-formation process of a first layer) based on a preset recipe. Here, when the first process is completed, the transferring mechanism of the main transfer chamber carries out the substrate from the first process module and carries the substrate into a second process module. The second process module also performs a second process (e.g. film-formation process of a second layer) based on a preset recipe. When the second process is completed, the transferring mechanism carries the substrate into a third process module in the case where there is a next process to be performed, or transfers the substrate back to the load-lock module in the case where there is no further process to be performed. In the case where a process is performed in the third process module or in a later process module, the transferring mechanism carries the substrate into a following process module in the case where there is a next process to be performed, or transfers the substrate back to the load-lock module in the case where there is no further process to be performed.

Accordingly, when the substrate, to which a series of processes are performed by the process modules, is carried into the load-lock module, the load-lock module is switched from depressurized state to atmospheric pressure state, and the substrate is carried out via a substrate outlet, which is on the opposite side of the main transfer chamber.

As described above, in a cluster tool, a group of substrates are sequentially transferred to a plurality of process modules at vacuum atmosphere one-by-one and a series of processes, e.g. plasma processes such as forming a plurality of films or etching process, are successively performed thereto (Patent Document 1: Japanese Laid-Open Patent Publication No. 2006-190894)

### DISCLOSURE OF THE INVENTION

### Technical Problem

However, when plasma processes, such as a forming or etching process of a plurality of films, are successively performed, it is necessary to extract a substrate from a process module and transfer the substrate to another process module at every film for forming a thin film or etching the thin film, in a conventional cluster tool. Therefore, due to the periods of time elapsed for transferring a substrate to each of processing modules, there is bags of room for improvement in throughput of plasma-processing on a substrate. Furthermore, since a plurality of process modules or a main transfer chamber is required, a substrate processing device occupies a large space.

The present invention is purposed to improve throughput of plasma-processing on a substrate by using a processing device, which occupies a relatively small space, for forming or etching a plurality of films of different compositions.

### Technical Solution

To resolve the technical problems stated above, the present invention provides a plasma processing system which forms or etches a plurality of films of different compositions, the plasma processing system including a plasma processing device which forms the plurality of films on a substrate or etches the plurality of films on a substrate by using plasma generated by supplying high frequency; a gas source which supplies all gases required for forming or etching the plurality of films into the plasma processing device; a plurality of gas pipes which separately introduce all the gases from the gas source to the plasma processing device; an exhausting device which exhausts exhaust gas generated in the plasma processing device; and a control device which selectively supplies gases required for forming or etching each of the plurality of films from the gas source to the plasma processing device via each of the gas pipes.

According to the present invention, since all gases required for forming or etching the plurality of films may be supplied into the plasma processing device from the gas source and gases required for forming or etching a film from among the plurality of films may be selectively supplied into the plasma processing device from the gas source by the control device, a plurality of films of different compositions may be formed or etched within a single plasma processing device. Therefore, it is not necessary to transfer a substrate to each of process modules per film-formation or per film-etching as in the conventional cluster tool, the throughput of plasma-processing with respect to a substrate may be improved. Furthermore, since a plurality of process modules and a main transfer chamber in a cluster tool are not necessary, the space occupied by a processing device (processing system) for forming or etching a plurality of films of different compositions may be reduced.

The control device includes a flow control device which controls flow of gas supplied into the plasma processing device, and the flow control device may measure the pressure of gas supplied to the plasma processing device and may control the flow of the gas to be supplied based on the measured pressure. Therefore, processing gas may always be supplied into the plasma processing device at suitable flow and suitable composition.

The plasma processing device includes a processing vessel which houses and processes a substrate; a holding unit in the processing vessel, on which a substrate is held; a high frequency supplying unit, which is formed at a location facing the substrate held on the holding unit and supplies high frequency for generating plasma uniformly with respect to 2 dimensions into the inside of the processing vessel; a plate-shaped structure, which is formed between the high frequency supplying unit and the holding unit and divides a region between the high frequency supplying unit and the holding unit into a region at the side of the high frequency supplying unit and a region at the side of the holding unit; a plasma gas source, which is formed at a location below the high frequency supplying unit to face the top surface of the structure and supplies gas for exciting plasma uniformly with respect to 2 dimensions to the region at the side of the high frequency supplying unit; and a gas supplying path which supplies gas from the plurality of gas pipes to the plasma gas source and the structure, and a plurality of processing gas supplying holes which supply processing gas for the film-formation or film-etching uniformly with respect to 2 dimensions to the region at the side of the holding unit and a plurality of openings via which plasma generated uniformly with respect to 2 dimensions in the region at the side of the high frequency supplying unit passes toward the region at the side of the holding unit may be formed in the structure. In this case, it may prevent a high frequency from entering the region at the side of the holding unit. Furthermore, since processing gas is uniformly supplied from the processing gas supplying holes of the structure to the region at the side of the holding unit, processing gas neither returns to the region at the side of the high frequency supplying unit nor is deposited on the inner surface of the processing vessel, and thus uniform gas flow may be embodied in the region at the side of the holding unit. Also, the term “plasma gas” is referred to as gas used for exciting plasma.

A gas protection film which contains no water molecules and no pinhole void and has corrosion-resistance with respect to plasma gas and processing gas may be formed in the inner surface of the processing vessel. Since the gas protection film having corrosion-resistance with respect to plasma gas and processing gas contains no water molecules, it may prevent water molecules from reacting with gas in the processing vessel and forming reaction products therein. Furthermore, according to a research made by the inventors, an Al₂O₃ film (aluminum oxide film), for example, is suitable as the gas protection film. Furthermore, such a gas protection film may withstand a high temperature between 100° C. and 200° C., for example.

The inner surface of the processing vessel may be heated to a temperature between 100° C. and 200° C. As a result, it may prevent reaction products generated in the processing vessel from being deposited on the inner surface of the processing vessel. Furthermore, to maintain the heated temperature, an insulation material may be formed on the outer surface of the processing vessel, and thus heats of the inner surface of the processing vessel will not escape out of the processing vessel, and energy may be saved.

The frequency of high frequency supplied from the high frequency supplying unit may be 915 MHz, 2.45 GHz, or 450 MHz. According to a research made by the inventors, when a high frequency with one of the frequencies is supplied, uniform plasma is stably generated in the processing vessel regardless of types, pressures, and composition concentrations of processing gas in the processing vessel.

The internal pressure of the exhausting device may continuously increase from the side of the entrance to the side of the exit. Therefore, generation of reaction products due to a dramatic pressure variation may be restricted.

The ratio between the pressure of exhaust gas at the side of the entrance of the exhausting device and the pressure of exhaust gas at the side of the exit of the exhausting device may be above 10,000, and the pressure of exhaust gas at the side of the exit of the exhausting device may be from about 0.4 kPa to about 4.0 kPa (from about 3 Torr to about 30 Torr). Since the pressure of exhaust gas at the exit side of the exhausting device may be increased, the diameter of an exhausting pipe connected to the exit side may be reduced.

The exhausting device may include a single stage vacuum pump or serially connected double stage vacuum pumps, the vacuum pump or pumps in each of the stages may be arranged singularly or arranged plurally in parallel, and flow of exhaust gas at the side of the exit of the exhausting device may be viscous flow. Therefore, since the conductance at the exit side of the exhausting device increases and exhaust gas may flow without reducing the exhaustion rate, even different types of exhaust gases may flow at a same rate. Furthermore, the term “viscous flow” is referred to as flow of gas above 133 Pa (1 Torr).

The vacuum pump of the exhausting device includes a screw vacuum pump, where the screw vacuum pump may includes interlocked rotors of which the angles of spiral of saw-toothed wheels are continuously changed; and a casing which houses the interlocked rotors, and may be configured such that the volumes of an operation chamber formed by the interlocked rotors and the casing is continuously reduced from the suction side to the ejection side of exhaust gas. Therefore, since the operation chamber performs suction, internal compression and transfer, and ejection of exhaust gas, the pressure of exhaust gas may be continuously increased, and thus local pressure increases in the screw vacuum pump may be restricted. As described above, since there is no dramatic pressure variation, formation of reaction products may be restricted.

An exhaust gas protection film which contains no water molecules and no pinhole void and has corrosion-resistance with respect to exhaust gas may be formed in the inner surface of the vacuum pump of the exhausting device. An Al₂O₃ film or a Y₂O₃ film, for example, may be used as such an exhaust gas protection film. Furthermore, the exhaust gas protection film may withstand a high temperature between 100° C. and 200° C., for example.

The inner surface of the vacuum pump or pumps of the exhausting device is heated to a temperature between 100° C. and 200° C. Furthermore, to maintain the heated temperature, an insulation material may be formed on the outer surface of the vacuum pump or pumps of the exhausting device.

A plurality of exhaust gas processing devices which process different types of exhaust gases generated in the plasma processing device, another exhausting device formed at the side of the exits of the plurality of exhaust gas processing devices, a plurality of first valves which control inflow of exhaust gas from the exhausting device to each of the exhaust gas processing devices, and a plurality of second valves which control inflow of processed exhaust gas from each of the exhaust gas processing device to the other exhausting device are formed at the downstream side of the exhausting device, where the plasma processing device, the exhausting device, the first valves, the exhaust gas processing devices, the second valves, and the other exhausting device may be connected via exhausting pipes in the order stated. Therefore, exhaust gas generated in the plasma processing device may be processed to be a harmless gas.

It is preferable for the first valves to be capable of operating with respect to exhaust gas at a temperature between 100° C. and 200° C.

A PFA film (poly(tetrafluoroethylene-co-perfluoroalkyl vinyl ether) resin film) or a fluorocarbon film may be formed on the surfaces of diaphragms of the first valves. Although a hyper-elastic alloy containing nickel, for example, is used in the diaphragms of valves, catalyst effect of nickel may be restricted, because the surfaces of the diaphragms are covered with a PFA film or a fluorocarbon film.

An exhaust gas protection film which contains no water molecules and no pinhole void and has corrosion-resistance with respect to exhaust gas may be formed in the inner surfaces of the first valves and the exhausting pipes. An Al₂O₃ film or a Y₂O₃ film, for example, may be used as such an exhaust gas protection film. Furthermore, the exhaust gas protection film may withstand a high temperature between 100° C. and 200° C., for example.

The inner surfaces of each of the first valves, the exhausting pipes which transfer exhaust gas from the exhausting device to the first valves, and the exhausting pipes which transfer exhaust gas from the first valves to the exhaust gas processing devices may be heated to a temperature between 100° C. and 200° C. Furthermore, to maintain the heated temperature, an insulation material may be formed on the outer surfaces of each of the first valves, the exhausting pipes which transfer exhaust gas from the exhausting device to the first valves, and the exhausting pipes which transfer exhaust gas from the first valves to the exhaust gas processing devices.

The other exhausting device may include a single stage vacuum pump or serially connected double stage vacuum pumps.

A collecting device for Kr and/or Xe and a third valve for selectively supplying exhaust gas containing Kr and/or Xe to the collecting device may be formed at the downstream side of the other exhausting device. Therefore, Kr gas (krypton gas) or Xe gas (xenon gas) may be re-used.

According to another embodiment of the present invention, there is provided a plasma processing method which forms or etches a plurality of films of different compositions, the plasma processing method for successively performing a first process for selectively supplying gas required for forming or etching a first film among the plurality of films into a processing vessel, which houses a substrate, as controlling flow of the gas and generating plasma 2-dimensionally and uniformly by 2-dimensionally and uniformly supplying high frequency into the processing vessel, so as to form or etch the first film by using the plasma; and a second process for selectively supplying gas required for forming or etching a second film among the plurality of films into the processing vessel and generating the plasma, so as to form or etch the second film by using the plasma.

It is preferable to exhaust exhaust gas from the processing vessel and to process the exhaust gas in the first process or the second process.

The second process may be performed immediately after the first process without interposing any other process therebetween.

After the first process, the second process may be performed after an inert gas is supplied into the processing vessel and the processing vessel is exhausted.

According to another embodiment of the present invention, there is provided a method of manufacturing an electronic device, the method including a process of successively forming or successively etching a plurality of films of different compositions based on the plasma processing method.

The electronic device may be a semiconductor device, a flat panel display device, or a solar battery.

### Advantageous Effects

According to the present invention, a plurality of films of different compositions may be formed or etched within a single plasma processing device. Therefore, the periods of time elapsed for transferring a substrate may be eliminated, and thus throughput of plasma-processing on the substrate may be improved. Furthermore, since a plurality of process modules and a main transfer chamber are not necessary, the space occupied by a processing device (processing system) for forming or etching a plurality of films of different compositions may be reduced.

### BRIEF DESCRIPTION OF THE DRAWINGS

FIG. 1 is a descriptive diagram schematically showing the configuration of a plasma processing system according to an embodiment of the present invention;

FIG. 2 is a plan view of a processing gas supplying structure;

FIG. 3 is a partial magnifying view of a vertical cross-section of the processing gas supplying structure in closer detail;

FIG. 4 is a descriptive diagram schematically showing the configuration of an exhausting device;

FIG. 5 is a horizontal cross-section of a screw booster pump;

FIG. 6 is a vertical cross-section of the screw booster pump;

FIG. 7 is a perspective view of a rotor of the screw booster pump;

FIG. 8 is a plan view of a rotor of the screw booster pump;

FIG. 9 is a descriptive diagram schematically showing the configuration of a plasma processing system according to another embodiment of the present invention;

FIG. 10 is a descriptive diagram schematically showing the configuration of an exhausting device;

FIG. 11 is a descriptive diagram schematically showing the configuration of the exhausting device;

FIG. 12 is a descriptive diagram schematically showing the configuration of the exhausting device;

FIG. 13 is a descriptive diagram schematically showing the configuration of the exhausting device;

FIG. 14 is a descriptive diagram schematically showing the configuration of another exhausting device;

FIG. 15 is a descriptive diagram schematically showing the configuration of a plasma processing device; and

FIG. 16 is a diagram showing states after each of plasma-processings according to the embodiments of the present invention, wherein FIG. 16(a) shows the state prior to etching, FIG. 16(b) shows the state after a SiCO film is etched, FIG. 16(c) shows the state after a resist film is ashed, FIG. 16(d) shows the state after a SiCN film and a CF film are etched, FIG. 16(e) shows the state after the SiCN film is etched, FIG. 16(f) shows the state after the CF film is etched, and FIG. 16(g) shows the state after the SiCN film is etched.

### BEST MODE FOR CARRYING OUT THE INVENTION

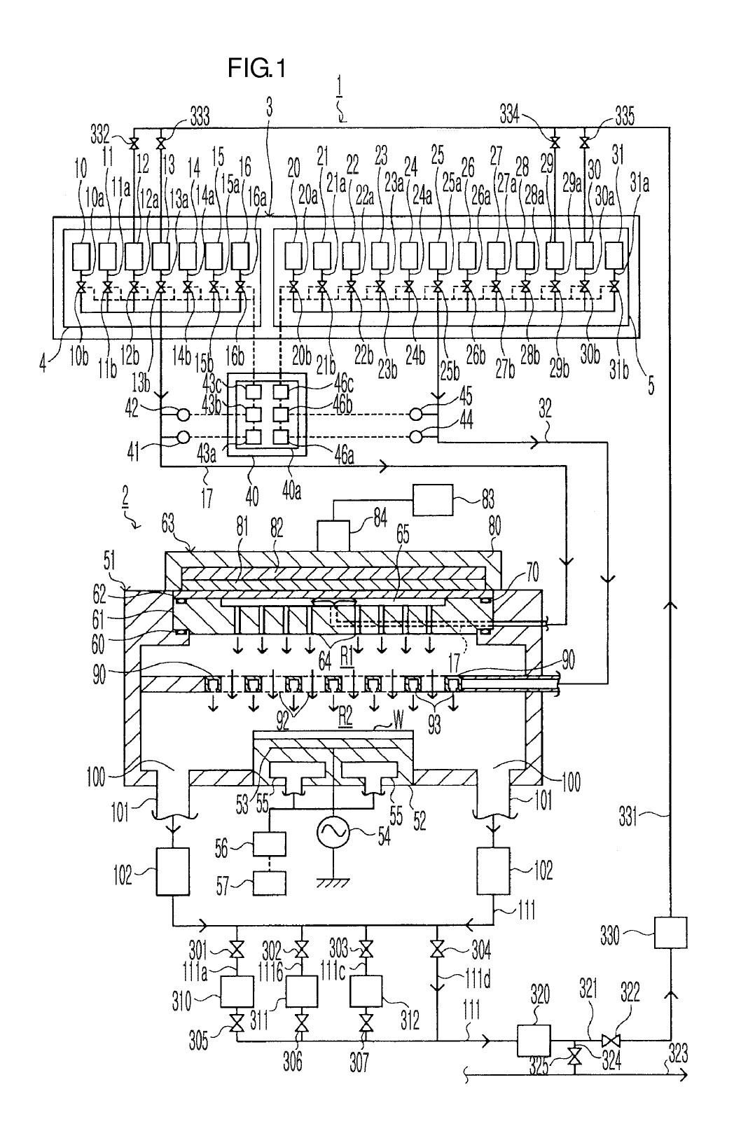

Hereinafter, embodiments of the present invention will be described. FIG. 1 is a diagram schematically showing the configuration of a plasma processing system 1 for forming a plurality of films of different compositions, which is an example of plasma-processing. In the present embodiment, a CVD (Chemical Vapor Deposition) method for generating plasma by using a radial line slot antenna is used for forming a film on a substrate.

As shown in FIG. 1, the plasma processing system 1 includes a plasma processing device 2 for forming a plurality of films on a substrate W and a gas source 3 for supplying all gas required for forming a plurality of films into the plasma processing device 2.

The gas source 3 includes a plasma gas source 4 for supplying plasma gas for exciting plasma into the plasma processing device 2 and a processing gas source 5 for supplying processing gas into the plasma processing device 2. The plasma gas source 4 includes seven gas enclosures 10 through 16, and the gas enclosures 10 through 16 enclose different types of plasma gases, respectively. For example, the gas enclosures 10 through 16 enclose NF₃ gas (trifluoro-nitrogen gas), Ar gas (argon gas), Xe gas (xenon gas), Kr gas (krypton gas), N₂ gas (nitrogen gas), O₂ gas (oxygen gas), and H₂ gas (hydrogen gas), respectively. Gas pipes 10a through 16a are connected to the gas enclosures 10 through 16, respectively, and valves 10b through 16b for controlling supply of plasma gas from the gas enclosures 10 through 16 are formed on the gas pipes 10a through 16a, respectively. The gas pipes 10a through 16a are connected to a gas supplying pipe 17, which is a path for supplying gas, at the downstream side of the valves 10b through 16b. Then, as the valves 10b through 16b are opened, the plasma gases or a mixture thereof, for example, is supplied into the plasma processing device 2 from the gas enclosures 10 through 16. The processing gas source 5 includes twelve gas enclosures 20 through 31, for example, and the gas enclosures 20 through 31 enclose different types of plasma gases, respectively. For example, the gas enclosures 20 through 31 enclose SiH₄ gas (monosilane gas), NH₃ gas (ammonia gas), PH₃ gas (phosphine gas), B₂H₆ gas (diborane gas), DCS gas (dichlorosilane gas), C₅F₈ gas (octafluorocyclopentene gas), CF₄ gas (tetrafluorocarbon gas), HBr gas (bromohydrogen gas), Cl₂ gas (chlorine gas), Xe gas (xenon gas), Kr gas (krypton gas), and Ar gas (argon gas), respectively. Gas pipes 20a through 31a are connected to the gas enclosures 20 through 31, respectively, and valves 20b through 31b for controlling supply of plasma gas from the gas enclosures 20 through 31 are formed on the gas pipes 20a through 31a, respectively. The gas pipes 20a through 31a are connected to a gas supplying pipe 32, which is a path for supplying gas, at the downstream side of the valves 20b through 31b. Then, as the valves 20b through 31b are opened, the processing gases or a mixture thereof, for example, is supplied into the plasma processing device 2 from the gas enclosures 20 through 31. Furthermore, the valves 10b through 16b and the valves 20b through 31b are opened and closed by a control device 40 connected to the valves 10b through 16b and 20b through 31b.

In the control device 40, a flow control device 40a for controlling flow of plasma gas and processing gas supplied into the plasma processing device 2 is formed. A thermometer 41 for measuring a temperature of plasma gas flowing in the gas supplying pipe 17 and a pressure gauge 42 for measuring a pressure of the plasma gas are formed at the gas supplying pipe 17 between the plasma gas source 4 and the plasma processing device 2. A temperature T₁ of plasma gas measured by the thermometer 41 is output to a temperature correction circuit 43a in the flow control device 40a. A pressure P₁ of plasma gas measured by the pressure gauge 42 is output to a flow calculating circuit 43b in the flow control device 40a. In the flow calculating circuit 43b, a flow of plasma gas is calculated via Q₁=KP₁ (here, K is an integer) and temperature of the flow Q₁ is corrected by using a correction signal from the temperature correction circuit 43a, and thus flow Q₁′ of plasma gas is calculated. The calculated flow Q₁′ is output to a comparison circuit 43c in the flow control device 40a. In the comparison circuit 43c, opening degrees of the valves 10b through 16b are calculated, such that the difference between the calculated flow Q₁′ and a flow Qₛ₁ of plasma gas configured based on a type of film-formation performed in the plasma processing device 2 becomes zero. The calculated opening degrees are output to the valves 10b through 16b, and thus the valves 10b through 16b are automatically controlled.

A thermometer 44 for measuring a temperature of processing gas flowing in the gas supplying pipe 32 and a pressure gauge 45 for measuring a pressure of the processing gas are formed at the gas supplying pipe 32 between the processing gas source 5 and the plasma processing device 2. Furthermore, same as the flow control of plasma gas described above, a temperature T₂ of processing gas measured by the thermometer 44 is output to a temperature correction circuit 46a in the flow control device 40a. A pressure P₂ of processing gas measured by the pressure gauge 45 is output to a flow calculating circuit 46b in the flow control device 40a. In the flow calculating circuit 46b, a flow of processing gas is calculated via Q₂=KP₂ (here, K is an integer) and temperature of the flow Q₂ is corrected by using a correction signal from the temperature correction circuit 46a, and thus flow Q₂′ of processing gas is calculated. The calculated flow Q₂′ is output to a comparison circuit 46c in the flow control device 40a. In the comparison circuit 46c, opening degrees of the valves 20b through 31b are calculated, such that the difference between the calculated flow Q₂′ and a configured flow Q_{S2} becomes zero. The calculated opening degrees are output to the valves 20b through 31b, and thus the valves 20b through 31b are automatically controlled.

The plasma processing device 2 includes an open-top cylindrical processing vessel 51 having the bottom. The processing vessel 51 is formed of an aluminum alloy, for example. The processing vessel 51 is grounded. An insulation material, e.g. glass wool, is formed on the outer surface of the processing vessel 51. The insulation material is formed to maintain the temperature of the inner surface of the processing vessel 51 heated by a heating device (not shown) at a temperature between 100° C. and 200° C. The inner surface of the processing vessel 51 is covered with an Al₂O₃ film without pinhole void, for example. The Al₂O₃ film is a gas protection film having corrosion-resistance with respect to plasma gas and processing gas, contains no moisture, and may withstand a temperature between 100° C. and 200° C. The Al₂O₃ film is fabricated by anodizing a metal mainly containing aluminum or a metal mainly containing high purity aluminum in a forming agent, which is from pH4 to pH10. At least one selected from a group including compounds of acids or bases exhibiting buffering effect between pH4 and pH10, for example, including boric acid, phosphoric acid, organic carbonic acid, and bases thereof, for example. A holding stage 52 is formed nearly at the center of the bottom of the processing vessel 51 for holding the substrate W thereon.

There is an electrode plate 53 in the holding stage 52, and the electrode plate 53 is connected to a high frequency power source 54 for 13.56 MHz bias, which is formed outside the processing vessel 51. When the surface of the holding stage 52 has negative electric potential due to the high frequency power source 54 for bias, positively charged particles in plasma may be attracted. Furthermore, since the electrode plate 53 is also connected to a direct current power source (not shown), the electrode plate 53 may form electrostatic force on the surface of the holding stage 52, so that the substrate W is electrostatically adhered to the holding stage 52.

A cooling jacket 55, which is a temperature controlling unit in which a coolant flows, is formed in the holding stage 52. The cooling jacket 55 is connected to a coolant temperature controlling unit 56, which controls the temperature of the coolant. In the coolant temperature controlling unit 56, the temperature of the coolant is controlled by a temperature controlling unit 57. Therefore, the temperature of the holding stage 52 may be controlled by configuring the temperature of the coolant to be controlled by the coolant temperature controlling unit 56 via the temperature controlling unit 57 and controlling the temperature of the coolant flowing in the cooling jacket 55 by the coolant temperature controlling unit 56. As a result, the temperature of the substrate W held on the holding stage 52 may be maintained below a predetermined temperature.

A shower plate 61 is formed on the top opening of the processing vessel 51 as a plasma gas supplying unit via a sealing member 60, such as an O-ring, for airtightness. The processing vessel 51 is closed by the shower plate 61. A cover plate 62 is formed substantially on the shower plate 61, and a radial line slot antenna 63 is formed substantially thereon as a high frequency supplying unit for supplying high frequency microwave for generating plasma uniformly in 2 dimensions.

The shower plate 61 is formed to have a shape of a disc, for example, and is arranged to face the holding stage 52. The shower plate 61 is formed of a material with high permittivity, e.g. aluminum nitride.

A plurality of gas supplying holes 64 penetrating in an approximately vertical direction are formed in the shower plate 61. Furthermore, in the shower plate 61, plasma gas from the gas supplying pipe 17 connected to the plasma gas source 4 passes through the shower plate 61 horizontally from a side of the processing vessel 51 through a gas inlet (not shown) and communicates with the top surface of the shower plate 61 and is supplied thereto from the center of the shower plate 61. A concave portion is formed on the top surface of the shower plate 61 with which the gas supplying path communicates, and a gas flowing path 65 is formed between the shower plate 61 and the cover plate 62. The gas flowing path 62 communicates with each of the gas supplying holes 64. Therefore, plasma gas supplied to the gas supplying pipe 17 is transferred to the gas flowing path 65, passes through each of the gas supplying holes 64 from the gas flowing path 65, and is supplied into the processing vessel 51 2-dimensionally and uniformly.

The cover plate 62 is adhered to the top surface of the shower plate 61 via a sealing member 70, such as an O-ring. The cover plate 62 is formed of a dielectric material, such as Al₂O₃, for example.

The radial line slot antenna 63 includes a near-cylindrical open-bottom antenna body 80. A disc-like slot plate 81, in which a plurality of slots are formed, is formed at the bottom opening of the antenna body 80. A wavelength-shortening plate 82, which is formed of a low-loss dielectric material, is formed on the top of the slot plate 81 in the antenna body 80. A coaxial waveguide 84, which communicates with a microwave oscillating device 83, is connected to the top of the antenna body 80. The microwave oscillating device 83 is installed outside of the processing vessel 51, and may emit microwave with a predetermined frequency, e.g. 2.4 GHz, with respect to the radial line slot antenna 63. Based on the configuration, a microwave emitted by the microwave oscillating device 83 propagates in the radial line slot antenna 63, becomes to have a shorter wavelength as being compressed at the wavelength-shortening plate 82, is circularly polarized at the slot plate 81, passes through the cover plate 62 and the shower plate 61, and is radiated into the processing vessel 51 2-dimensionally and uniformly. Furthermore, the frequency of the radiated microwave may be 915 MHz or 450 MHz.

A plate-shaped, for example, processing gas supplying structure 90 is formed between the holding stage 52 in the processing vessel 51 and the shower plate 61. The processing gas supplying structure 90 is formed to have a circular shape larger than the diameter of the substrate W at the least when viewed from above and to face the holding stage 52 and the shower plate 61. Due to the processing gas supplying structure 90, the interior of the processing vessel 51 is divided into a plasma exciting region R1 at the side of the shower plate 61 and a plasma diffusing region R2 at the side of the holding stage 52.

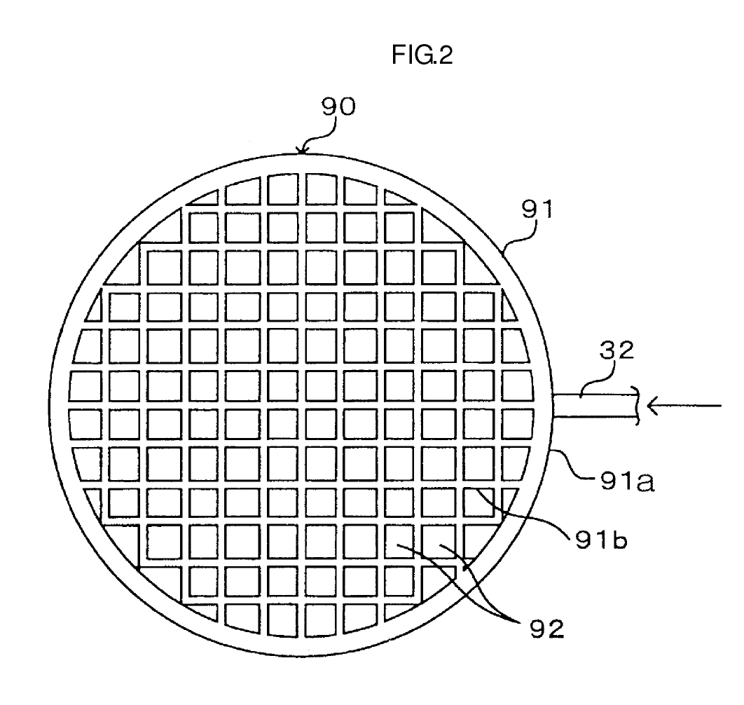

The processing gas supplying structure 90 is formed by a series of processing gas supplying pipes 91 which are arranged on the same plane in the shape close to a lattice, as shown in FIG. 2. The processing gas supplying pipes 91 include a loop pipe 91a, which is arranged as a loop in the outer perimeter of the processing gas supplying structure 90, and a lattice-shape pipe 91b, which is arranged inside of the loop pipe 91a such that a plurality of horizontal pipes and a plurality of vertical pipes cross each others. The processing gas supplying pipes 91 have rectangular vertical cross-sections as viewed in an axis direction and communicate with each others.

Furthermore, in the processing gas supplying structure 90, a plurality of openings 92 are formed in the spaces between the processing gas supplying pipes 91 arranged in form of a lattice. Plasma, which is generated 2-dimensionally and uniformly in the plasma exciting region R1 in the upper side of the processing gas supplying structure 90, passes through the openings 92 and enters the plasma diffusing region R2 at the side of the holding stage 52.

The size of each of the openings 92 is configured to be smaller than the wavelength of a microwave radiated by the radial line slot antenna 63. Accordingly, it may be prevent a microwave supplied by the radial line slot antenna 63 from entering the plasma diffusing region R2. As a result, the substrate W on the holding stage 52 is not directly exposed to the microwave, and thus damages to the substrate W due to the microwave may be prevented. The surface of the processing gas supplying structure 90, that is, the surface of the processing gas supplying pipes 91 is coated with a passivation film, for example, to prevent the processing gas supplying structure 90 from being sputtered by charged particles in plasma, and thus it may prevent substrate W from metal contamination due to particles popped out during sputtering.

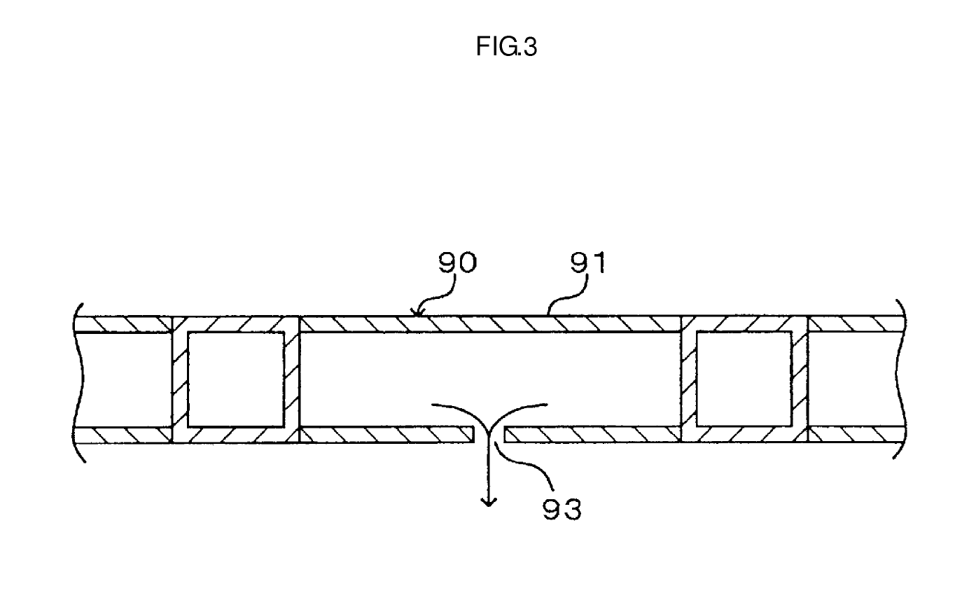

As shown in FIGS. 1 and 3, a plurality of processing gas supplying holes 93 are formed in the bottom surface of the processing gas supplying pipes 91 of the processing gas supplying structure 90. The processing gas supplying holes 93 are evenly arranged in the surface of the processing gas supplying structure 90. Alternatively, the processing gas supplying holes 93 may be evenly arranged in a region facing the substrate W held on the holding stage 52. As shown in FIG. 2, the gas supplying pipe 32 communicating with the processing gas source 5 installed outside the processing vessel 51 is connected to the processing gas supplying pipes 91 via a processing gas inlet (not shown). Therefore, processing gas supplied from the processing gas source 5 to the processing gas supplying pipe 91 via the gas supplying pipe 32 is ejected downward from each of the processing gas supplying holes 93 toward the plasma diffusing region R2 2-dimensionally and uniformly.

As shown in FIG. 1, exhausting holes 100 for exhausting the atmosphere inside the processing vessel 51 are formed at two locations, for example, in the bottom of the processing vessel 51. Through the exhaustion via the exhausting holes 100, the interior of the processing vessel 51 may be depressurized to a predetermined pressure, e.g. below 0.133 Pa (10⁻³ Torr). Exhausting pipes 101 are connected to the exhausting holes 100.

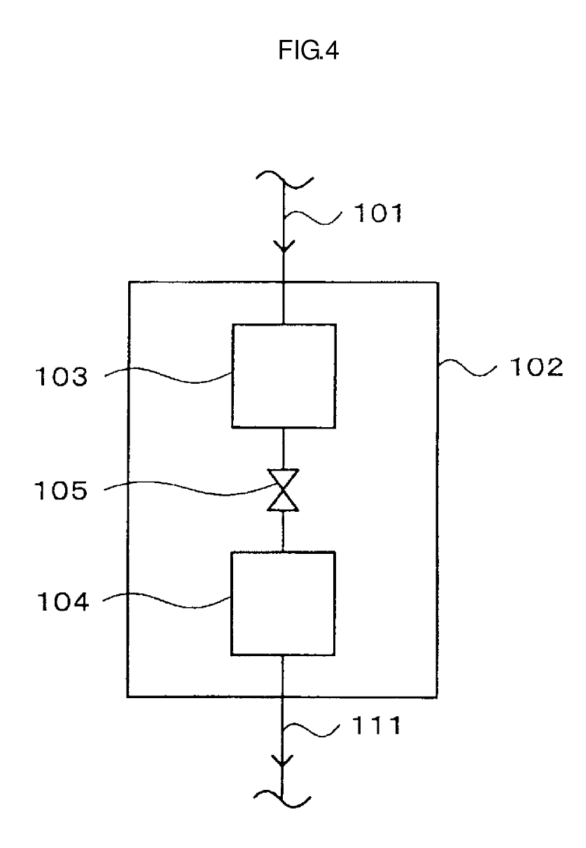

Exhausting devices 102 for sucking and exhausting the atmosphere inside the processing vessel 51 are formed at the exhausting pipes 101. As shown in FIG. 4, each of the exhausting devices 102 includes a first vacuum pump 103 and a second vacuum pump 104 that are arranged in double stages connected in series, for example. The first vacuum pump 103 and the second vacuum pump 104 are formed at the exhausting pipe 101 in the order stated above from the plasma processing device 2. A valve 105 is formed at the exhausting pipe 101 between the first vacuum pump 103 and the second vacuum pump 104.

Furthermore, insulation material, e.g. glass wool, is formed on the outer surface of each of the exhausting pipes 101, the first vacuum pumps 103, the second vacuum pumps 104, and the valves 105. The insulation material is formed to maintain the temperature of the inner surfaces of the exhausting pipes 101, the first vacuum pumps 103, the second vacuum pumps 104, and the valves 105 heated by a heating device (not shown) at a temperature between 100° C. and 200° C. Furthermore, the inner surfaces of the exhausting pipes 101, the first vacuum pumps 103, the second vacuum pumps 104, and the valves 105 are covered with Al₂O₃ films or Y₂O₃ films without pinhole void, for example. The Al₂O₃ film or the Y₂O₃ film is an exhaust gas protection film having corrosion-resistance with respect to exhaust gas, contains no moisture, and may withstand a temperature between 100° C. and 200° C.

Since exhaust gas flowing in the exhausting pipe 101 at the side of the entrance of the first vacuum pump 103 of the exhausting device 102 is depressurized to a predetermined pressure in the processing vessel 51, the flow thereof becomes a molecular flow, and the pressure thereof is below 0.133 Pa (10⁻³ Torr). Since the pressure of exhaust gas flowing in the exhausting pipe 101 between the first vacuum pump 103 and the second vacuum pump 104 increases due to suction of the first vacuum pump 103, the flow thereof becomes a viscous flow, and the pressure thereof is above 133 Pa (1 Torr). The pressure of exhaust gas flowing in the exhausting pipe 101 at the side of the exit of the second vacuum pump 104 is increased to a pressure from 0.4 kPa to 4.0 k Pa (from 3 Torr to 30 Torr), and the flow thereof becomes a viscous flow. Furthermore, it is maintained such that the ratio between the pressure of the exhaust gas at the side of the entrance of the first vacuum pump 103 and the pressure of the exhaust gas at the side of the exit of the second vacuum pump 104 is above 10,000. Here, the term “molecular flow” is referred to as flow of gas below 0.133 Pa (10⁻³ Torr), whereas the term “viscous flow” is referred to as flow of gas above 133 Pa (1 Torr).

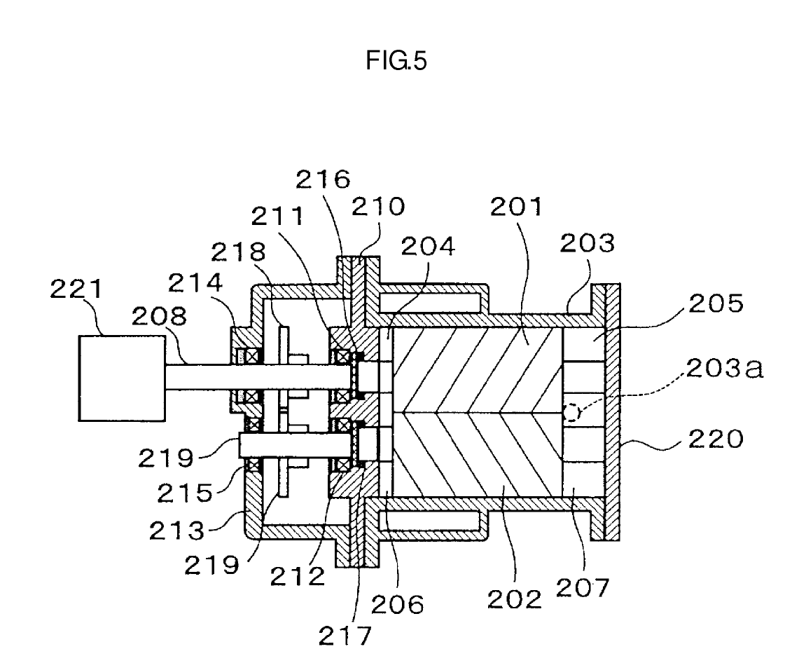

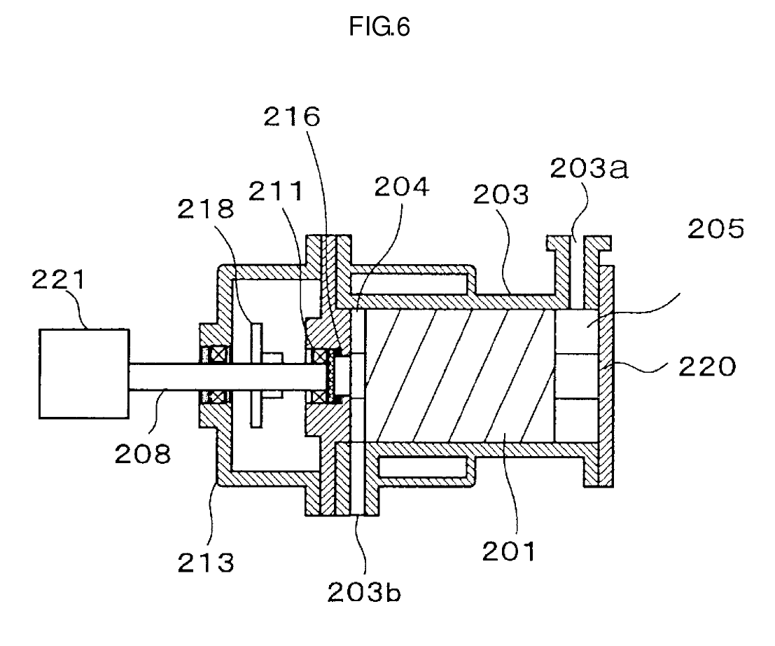

The first vacuum pump 103 is a turbo molecular pump (a screw pump), the second vacuum pump 104 is a screw booster pump, and, as shown in FIGS. 5 and 6, a male rotor 201 (a protruding rotor) and a female rotor 202 (a sunken rotor) are housed in a main casing 203. Both of the male rotor 201 and the female rotor 202 are referred to as couple rotors (interlocked rotors).

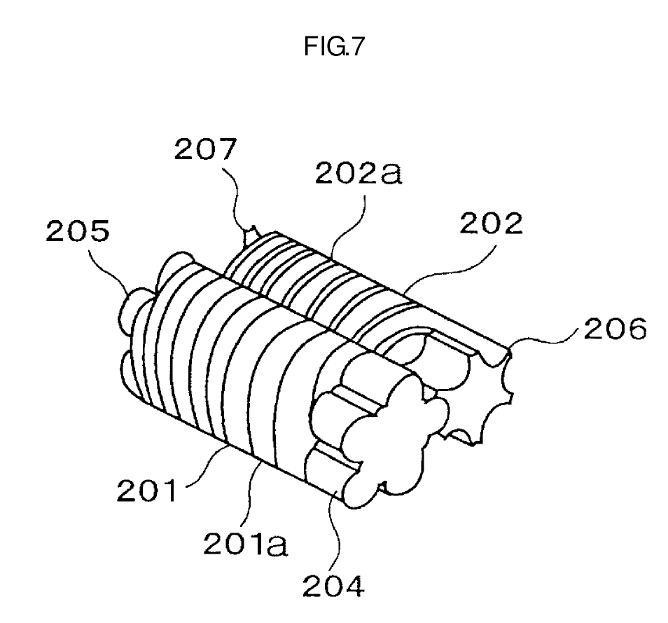

As shown in FIG. 7, the couple rotors 201 and 202 include screw saw-toothed wheels 201a and 202a, root units of the male side 204 and 205, and root units of the female side 206 and 207, where the root units of the male side 204 and 205 and the root units of the female side 206 and 207 are formed on two opposite ends of the screw saw-toothed wheels 201a and 202a, respectively. The angles of spirals of the screw saw-toothed wheels 201a and 202a are continuously changed based on angles at which the couple rotors 201 and 202 rotate. Furthermore, the volumes of V-shaped operation chambers 201b and 202b, which are formed by the couple rotors 201 and 202 and the main casing 203 as described below, are continuously changed.

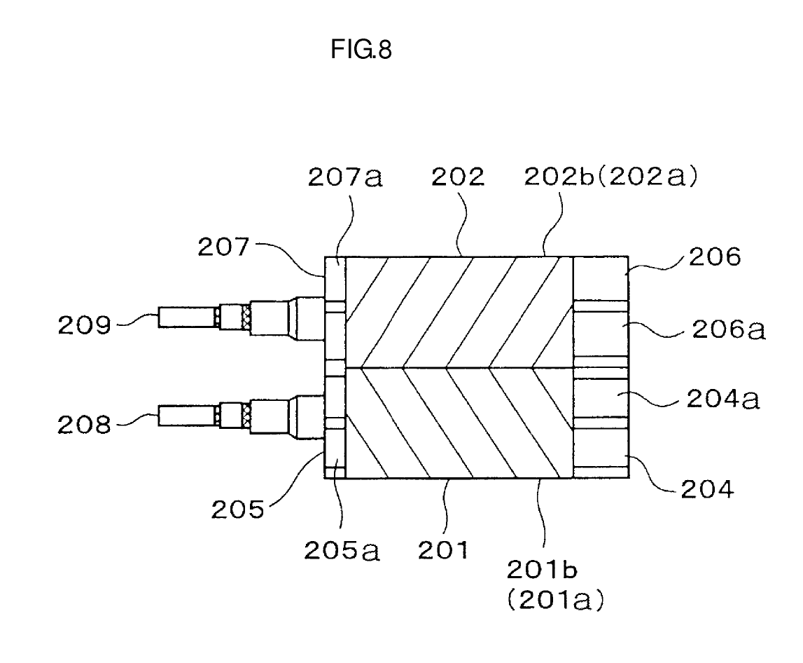

Furthermore, as shown in FIG. 8, the operation chambers 201b and 202b formed by the screw saw-toothed wheels 201a and 202b of the couple rotors 201 and 202 and the main casing 203 communicate with operations chambers 204a and 206a formed by the root unit of the male side 204, the root unit of the female side 206, and the main casing 203. In the same regard, the operation chambers 201b and 202b communicate with operations chambers 205a and 207a formed by the root unit of the male side 205, the root unit of the female side 207, and the main casing 203. Furthermore, rotation shafts 208 and 209 connected to a motor 221, shown in FIGS. 5 and 6, are formed at an end of the couple rotors 201 and 202.

As shown in FIGS. 5 and 6, the couple rotors 201 and 202 housed in the main casing 203 are supported by bearings 211 and 212, which are attached to an end plate 210 sealing an end surface of the main casing 203, and bearings 214 and 215, which are attached to a sub housing 213, such that the couple rotors 201 and 202 may freely rotate. An ejection hole 203b for ejecting gas compressed by the couple rotors 201 and 202 to the outside is formed in the side of the end plate 210 of the main casing 203. Furthermore, sealing members 216 and 217 are attached to the bearings 211 and 212, respectively, so that the sealing members 216 and 217 prevent lubricating oil by timing gears 218 and 219 described below from permeating into operation chambers.

As shown in FIGS. 5 and 6, the timing gears 218 and 219 housed in the sub casing 213 are attached to the rotation shafts 208 and 209 of the couple rotors 201 and 202, respectively, to adjust the two rotors, such that the couple rotors 201 and 202 do not contact each other. Furthermore, the bearings 211 and 212 are lubricated through splash oiling, and it is configured that lubricating oil (not shown) collected in the sub casing 213 is splashed by the timing gears 218 and 219. Furthermore, a sub casing 220 is attached to a second end side of the main casing 203. Furthermore, a suction hole 203a is formed at the second end side of the main casing 203.

In the first vacuum pump 103 and the second vacuum pump 104, which are configured as described above, gas is sucked from the suction hole 203a into the operation chambers 204a and 206a in accompaniment with rotation of the couple rotors 201 and 202. During the suction, sucked gas is compressed by the operation chambers 204a and 206b. Then, the compressed gas is transferred to the operation chambers 201b and 202b, which communicate with the operation chambers 204a and 206b. Although the operation chambers 201b and 202b transfers gas at a constant volume in accompaniment with rotation of the couple rotors 201 and 202, if the couple rotors 201 and 202 further rotate, the volume of the gas is reduced and the gas is compressed. Furthermore, the compressed gas is transferred to the operation chambers 205a and 207a, which communicate with the operation chambers 201b and 202b, and is compressed and ejected from the ejection hole 203b.

As shown in FIG. 1, the exhausting pipe 111 connected to the side of the exit of the exhausting device 102 having the configuration as described above is split into four exhausting pipes 111a through 111d, for example. Exhaust gas processing devices 310 through 312 are formed at the exhausting pipes 111a through 111c, respectively, where first valves 301 through 303 are formed at the upstream side of the exhaust gas processing devices 310 through 312, and second valves 305 through 307 are formed at the downstream side of the exhaust gas processing devices 310 through 312. The exhaust gas processing devices 310 through 312 are formed according to a type of exhaust gas exhausted from the plasma processing device 2, where, for example, the exhaust gas processing device 310 is a device for collecting PFC gas (perfluoro compound gas), the exhaust gas processing device 311 is a device for eliminating hydride, and the exhaust gas processing device 312 is a device for eliminating halogen. The exhausting pipe 111d is a pipe for flowing exhaust gas which may be exhausted as is, and only a first valve 304 is formed thereat. The exhausting pipes 111a through 111d are combined again at the downstream side, and are connected to a back pump 320.

Furthermore, the first valves 301 through 304 may operate even when the temperature of the inner surfaces of the first valves 301 through 304 rises to a temperature between 100° C. and 200° C., so that exhaust gas flowing in the first valves 301 through 304 is not cooled down and deposits are not formed on the inner surfaces of the first valves 301 through 304. Furthermore, insulation material, e.g. glass wool, is formed on the outer surface of each of the first valves 301 through 304, the exhaust gas processing devices 310 through 312, and the exhausting pipes 111 and 111a through 111d at the upstream side of the first valve 304 to maintain heated temperature. Furthermore, the inner surfaces of the first valves 301 through 304 and the exhausting pipes 111 and 111a through 111d are covered with Al₂O₃ films or Y₂O₃ films without pinhole void, for example. The Al₂O₃ film or the Y₂O₃ film is an exhaust gas protection film having corrosion-resistance with respect to exhaust gas, contains no moisture, and may withstand a temperature between 100° C. and 200° C. Furthermore, a PFA film or a fluorocarbon film is formed on the surfaces of diaphragms of the first valves 301 through 304. The PFA film or the fluorocarbon film may reduce catalyst effect of nickel. Furthermore, it is preferable to heating the inner surfaces of the exhaust gas processing devices 310 through 312, the exhausting pipes 101, 111, and 111a through 111d at the upstream side of the first valve 304, the exhausting device 102, and the first valves 301 through 304 to a temperature between 100° C. and 200° C., and more preferably, from about 150° C. to about 180° C. and to maintain the temperature, for the purpose above. It is not necessary for the exhaust gas processing devices 310 through 312, the downstream side thereof, and the downstream side of the first valve 304.

A collecting device 330 for collecting Kr gas and Xe gas in the exhaust gas via a collecting pipe 321 is connected at the downstream side of the back pump 320. A third valve 322 is formed at the collecting pipe 321. Furthermore, in the case where exhaust gas supplied from the back pump 320 contains at least Kr gas or Xe gas, the exhaust gas is selectively supplied to the collecting device 330 by the third valve 322. Furthermore, an exhausting pipe 324 for supplying exhaust gas not collected by the collecting device 330 to a factory-side exhausting line 323 is branched from the collecting pipe 321. A valve 325 is formed at the exhausting pipe 324, so that inflow of exhaust gas to the factory-side exhausting line 323 is controlled thereby. The collecting device 330 is connected to the gas enclosures 12, 14, 29, and 31 of the gas source 3 via a collecting pipe 331 and valves 332 through 335 formed at the collecting pipe 331. Then, Kr gas and Xe gas are refined from exhaust gas collected by the collecting device 330, and the refined Kr gas and Xe gas are selectively supplied to each of the gas enclosures 12, 14, 29, and 31. The plasma processing system 1 according to the present embodiment is configured as described above, and film-formation performed in the plasma processing system 1 will be described below. Here, descriptions are given with respect to the case in which a SiO₂ film (silicon oxide film), a Si₃N₄ film (silicon nitride film), a BPSG (Boron-Phosphor-Silicate-Glass) film, and a SiO₂ film are successively formed upward in the order stated above.

First, the substrate W is carried into the processing vessel 51 and is adhered to and held by the holding stage 52. Next, the exhausting device 102 begins to exhaust the interior of the processing vessel 51, and thus the interior of the processing vessel 51 is depressurized to a predetermined pressure, e.g. 0.133 PA (10⁻³ Torr).

When the interior of the processing vessel 51 is depressurized, to form a SiO₂ film, which is to be initially formed on the surface of the substrate W, the valves 11b and 15b of the plasma gas source 4 are opened by the flow control device 40a, and Ar gas and O₂ gas, which are plasma gases, flow from the gas enclosures 11 and 15 to the gas supplying pipe 17. At this point, flows of each of the Ar gas and the O₂ gas are controlled as the flow control device 40a controls the opening degrees of the valves 11b and 15b. Furthermore, the valve 20b of the processing gas source 5 is opened by the flow control device 40a, and SiH₄ gas, which is processing gas, flows from the gas enclosure 20 to the gas supplying pipe 32. At this point, flow of the SiH₄ gas is controlled as the flow control device 40a controls the opening degree of the valve 20b. Furthermore, the Ar gas, the O₂ gas, and the SiH₄ gas are supplied into the processing vessel 51 at the room temperature and the inner surface of the processing vessel 51 is heated to and maintained at a predetermined temperature, e.g. 150° C., by a heating device (not shown) to prevent deposits from being attached to the inner surface. Due to the attachment prevention, it is not necessary to perform a cleaning process after completion of film-formation, and a next process may be performed.

The Ar gas and O₂ gas, which are the plasma gases, pass through the gas supplying pipe 17 and are supplied toward the plasma exciting region R1 from the shower plate 61. Furthermore, a 2.45 GHz microwave is radiated from the radial line slot antenna 63 toward the plasma exciting region R1 below the same. Due to the microwave radiation, the Ar gas and the O₂ gas, which are the plasma gases, are plasmerized within the plasma exciting region R1. The plasma passes through the openings 92 of the processing gas supplying structure 90 and permeates into the plasma diffusing region R2 at the side of the holding stage 52.

Meanwhile, a voltage is applied to the holding stage 52 by the high frequency power source 54 for bias, and the plasma in the plasma exciting region R1 passes through the openings 92 of the processing gas supplying structure 90 and is diffused to the plasma diffusing region R2 below the processing gas supplying structure 90. The SiH₄ gas, which is processing gas, passes through the gas supplying pipe 32 and is supplied from the processing gas supplying holes 93 of the processing gas supplying structure 90 to the plasma diffusing region R2. The SiH₄ gas is radicalized by plasma supplied from above, for example and is reacts with the oxygen radical in the plasma, and a SiO₂ film is deposited and grows on the substrate W.

While plasma gas and processing gas are supplied into the plasma processing device 2 and a SiO₂ film is formed on the substrate W as described above, exhaust gas generated in the plasma processing device 2 is exhausted to the exhaust gas processing device 311 via the exhausting pipes 101 and 111 and the first valve 302 by the exhausting device 102 and the first valve 302. The exhaust gas is exhausted by the exhausting device 102 at a same rate throughout the process of forming the SiO₂ film. Then, hydride among the exhaust gas exhausted to the exhaust gas processing device 311 is removed from the exhaust gas in the exhaust gas processing device 311. The exhaust gas from which hydride is removed does not contain Kr gas and Xe gas, and is exhausted to the factory-side exhausting line 323 from the back pump 320 by the valve 325.

Next, when the SiO₂ film grows and a SiO₂ film with a predetermined thickness is formed on the substrate W, microwave is radiated and plasma gas and processing gas are switched to gases for next film-forming process.

In other words, to form a Si₃N₄ film on the SiO₂ film on the substrate W, the valves 11b and 15b of the plasma gas source 4 are closed and the valve 12b is opened simultaneously by the flow control device 40a, and Xe gas, which is plasma gas, flows from the gas enclosure 12 to the gas supplying pipe 17. Furthermore, the valve 20b of the processing gas source 5 is closed and the valves 21b and 24b are opened simultaneously by the flow control device 40a, and NH₃ gas and DCS gas, which are processing gases, flow from the gas enclosures 21 and 24 to the gas supplying pipe 32. Furthermore, the Xe gas, the NH₃ gas, and the DCS gas are supplied into the processing vessel 51 at the room temperature. The inner surface of the processing vessel 51 is maintained at a predetermined temperature, e.g. 150° C., by a heating device (not shown).

Furthermore, the Xe gas, which is the plasma gas, is supplied from the shower plate 61 toward the plasma exciting region R1, and, due to microwave radiation of the radial line slot antenna 63, the plasma gas is plasmerized. The plasma of the plasma exciting region R1 passes through the openings 92 of the processing gas supplying structure 90 and is diffused into the plasma diffusing region R2 below the processing gas supplying structure 90. Meanwhile, the NH₃ gas and the DCS gas, which are the processing gases, are supplied from the processing gas supplying holes 93 of the processing gas supplying structure 90 toward the plasma diffusing region R2. Then, in the plasma diffusing region R2, the processing gas is radicalized by and reacts with plasma supplied from above, and a Si₃N₄ film is deposited and grows on the substrate W. Meanwhile, exhaust gas is transferred to the collecting device 330 after hydride is removed from the exhaust gas in the exhaust gas processing device 311, and Xe gas is collected. After completion of formation of the Si₃N₄ film, microwave is radiated and plasma gas and processing gas are switched.

In other words, for formation of a BPSG film on the substrate W, Ar gas and O₂ gas, which are plasma gases, and SiH₄ gas, PH₃ gas, and B₂H₆ gas, which are processing gases, are supplied from the gas source 3 into the plasma processing device 2, and the BPSG film is formed on the Si₃N₄ film on the substrate W in the same manner as the formations of SiO₂ film and Si₃N₄ film described above.

Then, for formation of a SiO₂ film on the substrate W, due to the switching of gases from the gas source 3, Ar gas and O₂ gas, which are plasma gases, and SiH₄ gas, which is processing gas, are supplied into the plasma processing device 2, and the SiO₂ film is formed on the BPSG film on the substrate W.

As described above, formations of predetermined films on the substrate W are repeated as continuously exhausting the interior of the plasma processing device 2, and the SiO₂ film, the Si₃N₄ film, the BPSG film, and the SiO₂ film are successively formed upward in the order stated above. Then, the substrate W is carried out of the processing vessel 51, and a series of plasma film-formations are completed.

According to the above embodiment, since plasma gas and processing gas are selectively supplied from the gas source 3 to the plasma processing device 2 40a according to predetermined films to be formed on the substrate W by the flow control device, formations of a plurality of films of different compositions may be performed on the substrate W within the single plasma processing device 2. Therefore, it is not necessary to transfer the substrate W to each of process modules per film-formation as in the conventional cluster tool, and the throughput of film-formation process with respect to the substrate W may be improved. Furthermore, since a plurality of process modules and a main transfer chamber in a cluster tool are not necessary, the space occupied by the plasma processing system 1 may be reduced.

Furthermore, since the flow control device 40a for controlling flows of plasma gas and processing gas supplied into the plasma processing device 2 is formed in the control device 40, plasma gas and processing gas may always be supplied at suitable flow and suitable composition. Furthermore, since the inner surface of the plasma processing device 2 is maintained at 150° C., it may prevent reaction products generated in the processing vessel 51 from being deposited on the inner surface of the processing vessel 51.

Furthermore, the frequency of microwave radiated from the radial line slot antenna 63 is 2.45 GHz, microwave is uniformly radiated by using the radial line slot antenna 63, gas is uniformly discharged by the shower plate 61 and is exhausted as maintaining uniform gas flow, and thus, regardless of types, pressures, and composition concentrations of plasma gas and processing gas supplied into the processing vessel 51, more uniform plasma may be stably generated in the processing vessel 51 and successive film-formations may be performed within the single processing vessel 51. Since the processing gas is uniformly supplied from the processing gas supplying holes 93 of the processing gas supplying structure 90 to the plasma diffusing region R2, processing gas neither returns to the plasma exciting region R1 nor is deposited on the inner surface of the processing vessel 51, and thus uniform gas flow may be embodied in the plasma diffusing region R2.

Furthermore, an Al₂O₃ film, which is gas protection film with corrosion-resistance with respect to plasma gas and processing gas, is formed on the inner surface of the processing vessel 51 and the Al₂O₃ film contains no water molecules, and thus it may prevent water molecules from reacting with gas in the processing vessel 51 and forming reaction products in the processing vessel 51. Furthermore, since the Al₂O₃ film may withstand a temperature between 100° C. and 200° C., no problems due to heating of the inner surface of the processing vessel 51 may occur. Furthermore, since an insulation material is formed on the outer surface of the processing vessel 51, even if the inner surface of the processing vessel 51 is maintained at a high temperature of 150° C., the heat does not escape out of the processing vessel 51, and thus energy may be saved.

Furthermore, since the exhausting device 102 includes the first vacuum pump 103 and the second vacuum pump 104, which are screw booster pumps, and may maintain the pressure of exhaust gas at the side of the exit of the second vacuum pump 104 as high as from 0.4 kPA to 40 kPA (from 3 Torr to 30 Torr), the diameter of the exhausting pipe 111 connected to the side of the exit may be reduced. Furthermore, since the flow of exhaust gas in the exhausting pipe 111 at the side of the exit of the second vacuum pump 104 becomes viscous flow, the conductance at the side of the exit of the second vacuum pump 104 increases and exhaust gas may flow without reducing the exhaustion rate, and thus even different types of exhaust gases may flow at a same rate. Furthermore, since the angles of spirals of the saw-toothed wheels of the couple rotors 201 and 202 of the first vacuum pump 103 and the second vacuum pump 104 are continuously changed, the pressure of exhaust gas may be continuously increased by continuously reducing the volumes of the operation chambers 201b and 202b. Accordingly, since local pressure increases in the first vacuum pump 103 and the second vacuum pump 104 may be restricted, generation of reaction products due to a dramatic pressure variation may be restricted.

Furthermore, since the inner surfaces of the first vacuum pumps 103, the second vacuum pumps 104, and the valve 105 of the exhausting device 102, the exhausting pipes 101, 111, and 111a through 111d, and the first valves 301 through 303 are covered with Al₂O₃ films or Y₂O₃ films having corrosion-resistance with respect to exhaust gas and the Al₂O₃ films or the Y₂O₃ films contain no water molecules, it may prevent water molecules from reacting with exhaust gas in the exhausting device 102 and generating reaction products, the exhausting pipes 101, 111, and 111a through 111d, and the first valves 301 through 303. Furthermore, since the Al₂O₃ films or the Y₂O₃ films may withstand a temperature between 100° C. and 200° C., it may withstand exhaust gas, of which the temperature is 150° C., exhausted from the processing vessel 51. Furthermore, since the inner surfaces of the exhausting device 102, the exhausting pipes 101, 111, and 111a through 111d at the upstream side of exhaust gas processing devices 310 through 312 and the first valve 304, and the first valves 301 through 303 are heated to temperatures between 100° C. and 200° C. and an insulation material is formed on the outer surfaces thereof, attachment of deposits may be prevented while energy is saved.

Furthermore, since a PFA film or a fluorocarbon film is formed on the surfaces of diaphragms of the first valves 301 through 303, even if a hyper-elastic alloy containing nickel is used in the diaphragms of the first valves 301 through 303, catalyst effect of nickel may be restricted.

Although the plasma processing system 1 includes one plasma processing device 2 in the above embodiment, the plasma processing system 1 may further include a magnetron sputter device for forming a metal film on a substrate. In the magnetron sputter device, a substrate held on the holding stage in a processing vessel and a target formed by joining a plate, e.g. a copper plate, to a disc, which is a raw material of a thin-film, are arranged to face each other. Then, when a negative high voltage is applied to the target and plasma gas, e.g. Ar gas or H₂ gas, is supplied into the processing vessel, the Ar gas or the H₂ gas is plasmerized by high electric field and is positively ionized. Then, when a direct current voltage is applied using the target as a cathode side and the substrate side as an anode, Ar ions or H₂ ions that are accelerated to high speed collide with the target. As a result, atoms of the raw material of the target are pushed by the Ar ions or H₂ ions like billiard balls and pop out, and the popped out atoms are attached to the substrate, and thus a predetermined film grows. Accordingly, by using the plasma processing system 1 having a magnetron sputter device, the magnetron sputter device may be used for forming a metal film on a substrate and the plasma processing device 2 may be used to form a non-metal film, for example, and thus a plurality of films may be efficiently formed on a substrate.

Although plasma gas and processing gas for forming a Si₃N₄ film are continuously switched and supplied into the plasma processing device 2 after the formation of a SiO₂ film in the above embodiment, an inert gas, e.g. Ar gas, may be supplied into the plasma processing device 2 to exhaust the interior of the plasma processing device 2 before plasma gas and processing gas are switched, and then plasma gas and processing gas may be switched. Furthermore, Ar gas may be supplied into the plasma processing device 2 to exhaust the interior of the plasma processing device 2 after the formation of Si₃N₄ film, before supplying plasma gas and processing gas for forming a BPSG film, and before supplying plasma gas and processing gas for forming a SiO₂ film after the formation of the BPSG film. In this case, after formation of a predetermined film, exhaust gas generated while the film is being formed may be completely exhausted from the plasma processing device 2, and thus a next film may be formed suitably.

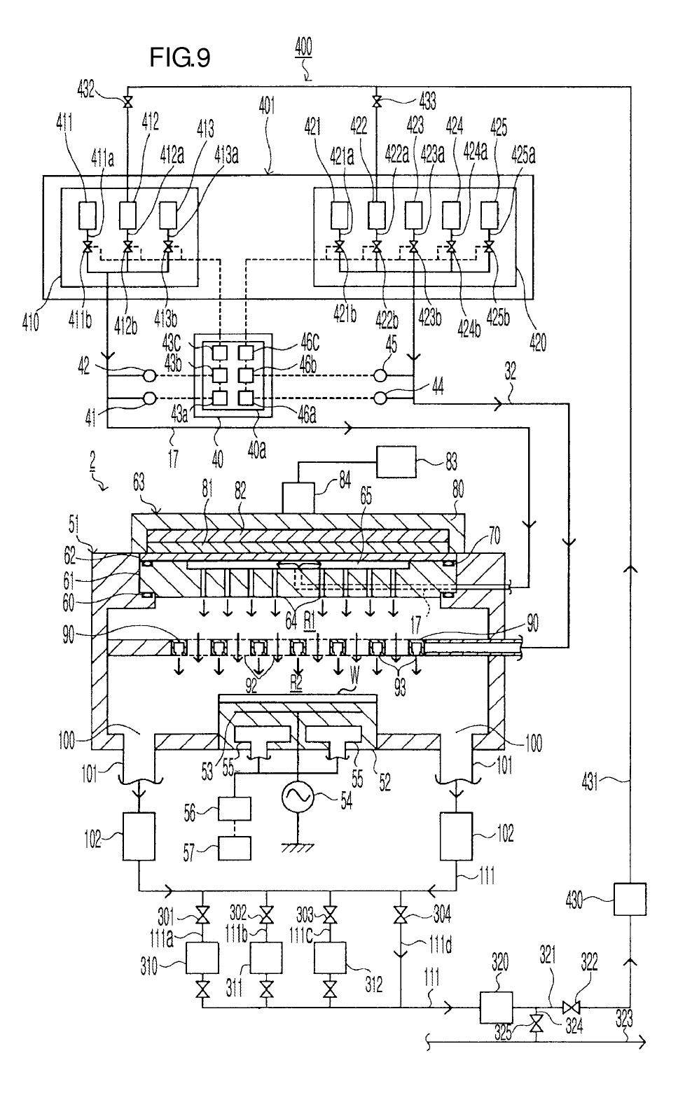

Although the plasma processing system 1 is for forming a plurality of films on the substrate W in the above embodiment, the plurality of films formed on the substrate W may be successively etched by using a plasma processing system 400 shown in FIG. 9. In the present embodiment, successive etching process in the case where a resist film, a hard mask (SiCO film), a SiCn film, a CF film, a SiCN film, a CF film, and a SiCN film are formed on the substrate in the order opposite to the order stated above will be described.

Instead of the gas source 3 in the plasma processing system 1, the plasma processing system 400 includes a gas source 401. The gas source 401 includes a plasma gas source 410 for supplying plasma gas and a processing gas source 420 for supplying processing gas. The plasma gas source 410 includes three gas enclosures 411, 412, and 413, for example, and Ar gas, Xe gas, and O₂ gas, for example, are enclosed in the enclosures 411, 412, and 413, respectively. Gas pipes 411a, 412a, and 413a are respectively connected to the gas enclosures 411, 412, and 413, and valves 411b, 412b, and 413b for controlling supply of plasma gas from the gas enclosures 411, 412, and 413 are respectively formed at the gas pipes 411a, 412a, and 413a. The processing gas source 420 includes five gas enclosures 421 through 425, for example, and Ar gas, Xe gas, CF₄ gas, C₄F₈ gas, and C₅F₈ gas, for example, are enclosed in the enclosures 421 through 425, respectively. Gas pipes 421a through 425a are respectively connected to the gas enclosures 421 through 425, and valves 421b through 425b for controlling supply of processing gas from the gas enclosures 421 through 425 are respectively formed at the gas pipes 421a through 425a.

Furthermore, instead of the collecting device 330 in the plasma processing system 1, the plasma processing system 400 includes a collecting device 430 for collecting Xe gas. The collecting device 430 is connected to the gas enclosures 412 and 422 of the gas source 401 via a collecting pipe 431 and valves 432 and 433 formed at the collecting pipe 431. The remaining configuration of the plasma processing system 400 is identical to that of the plasma processing system 1.

Then, in the same manner as successively forming predetermined films on the substrate W as described above, the atmosphere in the processing vessel 51 is depressurized first, and Ar gas, which is plasma gas for etching a hard mask on the substrate W, and Ar gas, C₅F₈ gas, and CF₄ gas, which are processing gases, are supplied into the processing vessel 51. Then, a high frequency power is applied into the processing vessel 51, and reactive plasma is generated from the plasma gas by the high frequency power. Then, due to reaction of the reactive plasma with the processing gases, the hard mask on the substrate W is etched. Here, while the hard mask on the substrate W is being etched, exhaust gas generated in the plasma processing device 2 is exhausted by the exhausting device 102. Then, after the hard mask is etched, gases are switched for a next process while the high frequency power is continuously applied.

In other words, to perform plasma-ashing to peel off a resist film, Ar gas and O₂ gas are supplied into the processing vessel 51. Then, reactive plasma is generated in the same manner as described above, the resist film is plasma-ashed, and switching and supplying of gas and film-etching are successively performed with respect to a SiCN film, a CF film, a SiCn film, a CF film, and a SiCN film formed on the substrate W in the same manner as described above. Furthermore, Ar gas is used as plasma gas and Ar gas and CF₄ gas are used as processing gases for etching the topmost SiCN film, whereas Xe gas is used as plasma gas and Xe gas and C₄F₈ gas are used as processing gases for etching the middle and the bottommost SiCN films. Furthermore, Ar gas is used as plasma gas and Ar gas and CF₄ gas are used as processing gases for etching the CF film. In the case where Xe gas is used as plasma gas, exhaust gas in the processing vessel 51 contains Xe gas, and Xe gas is collected from the exhaust gas by the collecting device 430 as the third valve 322 is opened. Then, in the collecting device 430, Xe gas is refined from the exhaust gas and the Xe gas is supplied to either the gas enclosure 412 or the gas enclosure 422.

As described above, according to the present embodiment, process of etching a predetermined film may be performed successively and repeatedly within a single device by switching gases to be supplied according to a predetermined film on the substrate W and switching other etching conditions, and thus a plurality of films of different compositions on the substrate W may be successively etched.

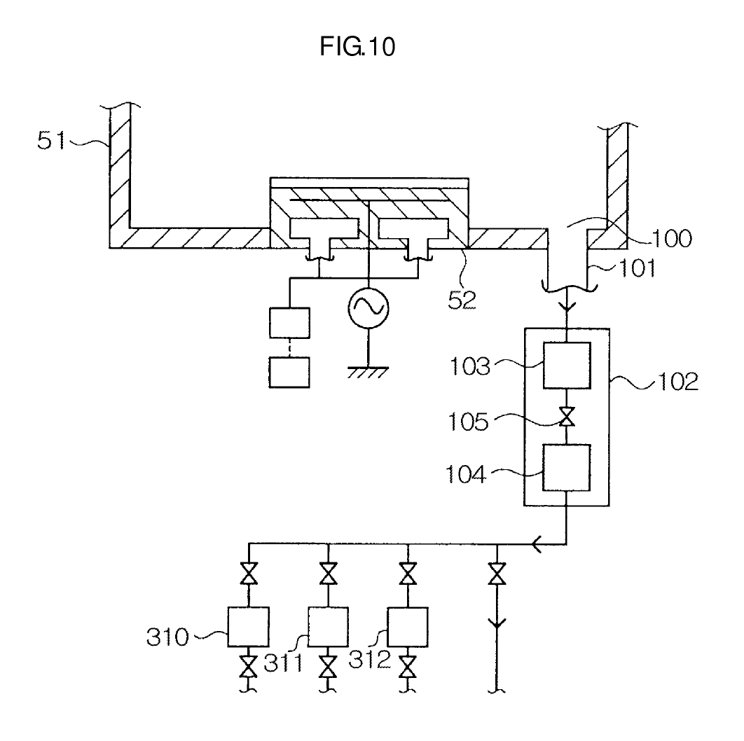

Although two exhausting devices 102 are formed at two locations of the bottom of the processing vessel 51 in the above embodiment, one exhausting device 102 may be formed at one location, as shown in FIG. 10. Alternatively, three or more exhausting devices 102 may be formed at locations symmetrical with respect to the substrate W. Furthermore, either of a screw booster pump or a turbo molecular pump may be used as the first vacuum pump 103. Furthermore, a screw booster pump is used as the second vacuum pump 104.

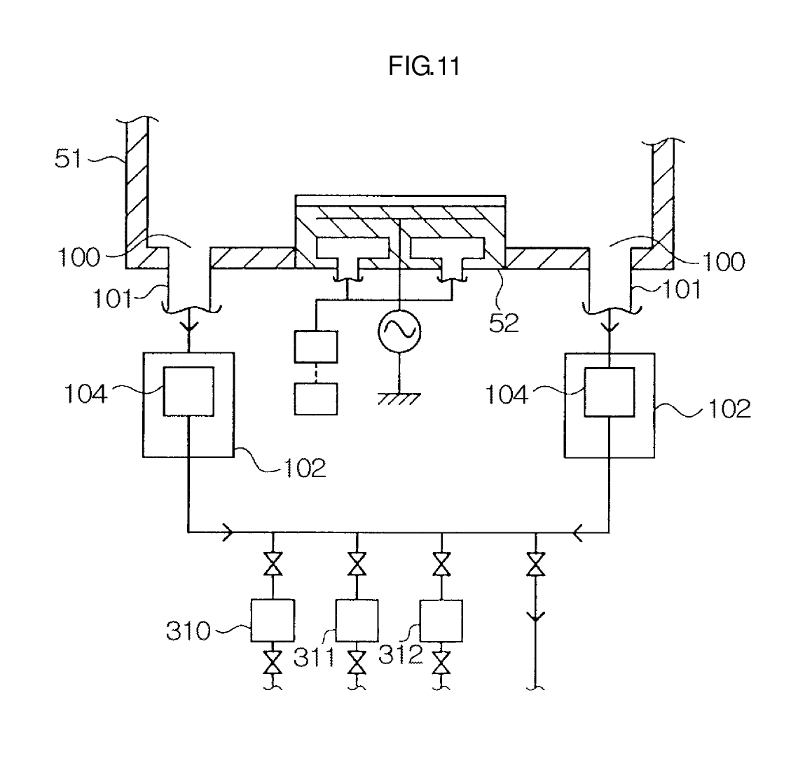

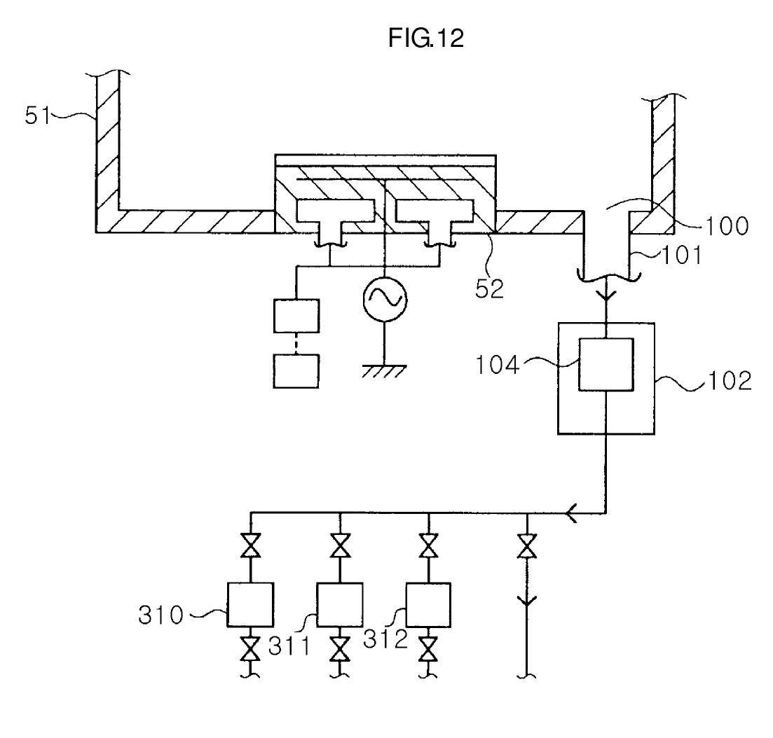

Although the double stage vacuum pumps (the first vacuum pump 103 and the second vacuum pump 104) are arranged in series in the exhausting device 102 in the above embodiment, only one vacuum pump (the second vacuum pump 104) may be arranged as shown in FIG. 11. In this case, a screw booster pump is used as the second vacuum pump 104. Furthermore, as shown in FIG. 12, such the exhausting device 102 may be formed at one location with respect to the processing vessel 51.

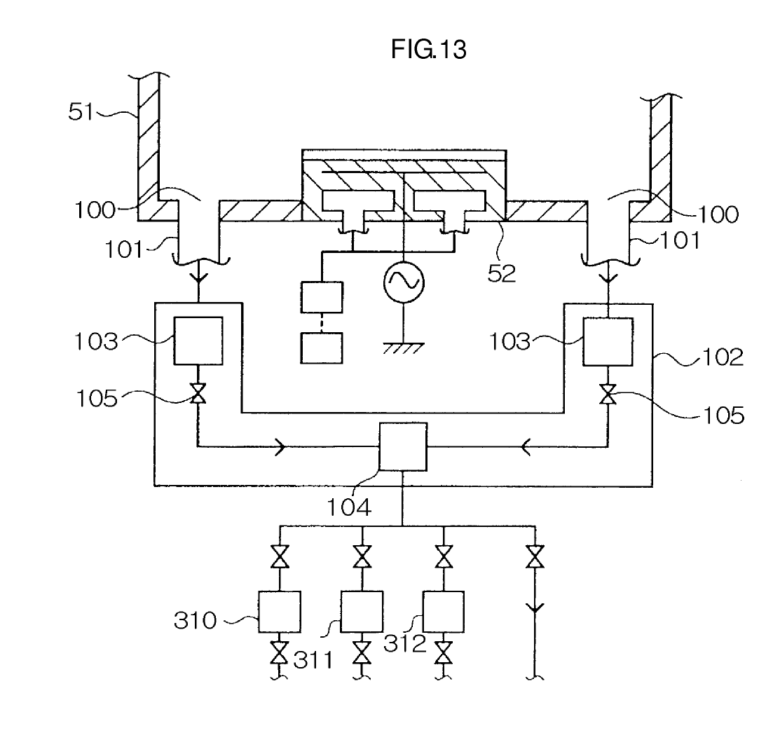

Although the second vacuum pump 104 is arranged in series with one first vacuum pump 104 in the above embodiment, one second vacuum pump 104 may be formed with respect to two first vacuum pumps 103 and 103 as shown in FIG. 13. In this case, either a screw booster pump or a turbo molecular pump may be used as the first vacuum pumps 103. Furthermore, a screw booster pump is used as the second vacuum pump 104.

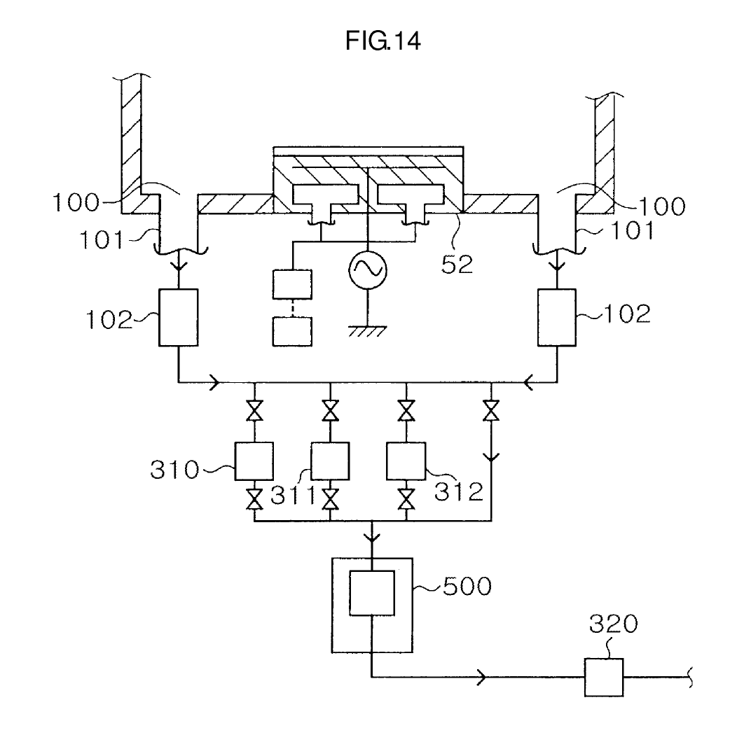

Although the back pump 320 is connected to the exhaust gas processing devices 310 through 312 and the exhausting pipe 111d in the above embodiment, another exhausting device 500 may be formed between the exhaust gas processing devices 310 through 312 and the exhausting pipe 111d, and the back pump 320 as shown in FIG. 14. The other exhausting device 500 may include a screw booster pump.

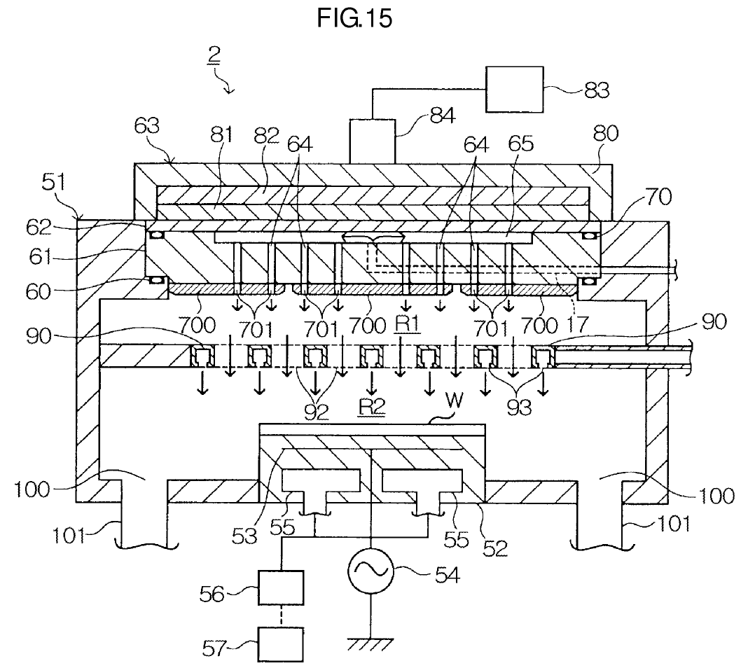

In the plasma processing device 2 according to the above embodiment, a metal plate 700 may be formed on the bottom surface of the shower plate 61, as shown in FIG. 15. The metal plate 700 is formed of a material with electrical conductivity, e.g. an aluminum alloy. A plurality of the metal plates 700 are formed to expose a portion of the shower plate 61 in the processing vessel 51. Each of the metal plates 700 are formed, such that the metal plates 700 have almost same size. Therefore, microwave (conductor surface wave) propagating from the shower plate 61 propagates with respect to the metal plates 700 at almost constant state. As a result, plasma may be generated by microwave at overall uniform conditions on the bottom surface of the metal plates 700. Furthermore, the term “conductor surface wave” is referred to as microwave propagating along metal surfaces between the metal surfaces and plasma. Furthermore, a plurality of gas supplying paths 701 communicating with the gas supplying holes 64 are formed in each of the metal plates 700. The gas supplying paths 701 are formed at locations corresponding to those of the gas supplying holes 64, for example. Therefore, plasma gas supplied to the gas supplying pipe 17 passes through the gas flowing path 65, the gas supplying holes 64, and the gas supplying paths 701 and is supplied uniformly in 2 dimensions with respect to the inside of the processing vessel 51.

Furthermore, microwave of which the frequency is below 2 GHz, e.g. 915 MHz or 450 MHz, is oscillated from the microwave oscillating device 83 with respect to the radial line slot antenna 63.

In the case where the plasma processing device 2 is used, during plasma-processing, microwave propagating from the microwave oscillating device 83 to the shower plate 61 propagates along the bottom surface of the metal plate 700 from the shower plate 61 exposed in the plasma exciting area R1 in the processing vessel 51 as a conductor surface wave. Due to the conductor surface wave, plasma gas is plasmerized in the plasma exciting region R1. At this point, as described above, plasma is generated by microwave at overall uniform conditions on the bottom surface of the metal plates 700 and the plasma gas is supplied uniformly in 2 dimensions with respect to the inside of the processing vessel 51, and thus it is possible to perform uniform plasma-processing throughout a surface of the substrate W to be processed.

Furthermore, although plasma is excited by dielectric surface wave on a portion of the shower plate 61 exposed in the processing vessel 51, the dielectric surface wave applies microwave electric field to both the shower plate 61 and plasma. On the contrary, conductor surface wave propagating along the bottom surface of the metal plates 700 applies microwave electric field only to plasma, and thus the intensity of microwave electric field applied to the plasma may be strengthened. Therefore, plasma with higher density may be excited on the surfaces of the metal plates 700 as compared to the surface of the shower plate 61. Furthermore, in case of using microwave with a relatively low frequency below 2 GHZ, the minimum electron density for obtaining stable plasma with low electron temperature may be lowered as compared to the case where microwave with a high frequency is used, and thus plasma suitable for plasma-processing may be obtained under broader conditions.

While the present invention has been particularly shown and described with reference to exemplary embodiments thereof, it will be understood by those of ordinary skill in the art that various changes in form and details may be made therein without departing from the spirit and scope of the present invention as defined by the following claims. A substrate according to the present invention may be applied to manufacturing of electronic devices, such as a semiconductor wafer, a liquid crystal display, an organic EL display, a mask reticle for a photomask, or the like. Furthermore, the present invention may be applied to manufacturing of electronic devices, such as a solar battery or the like.

### Mode for Invention

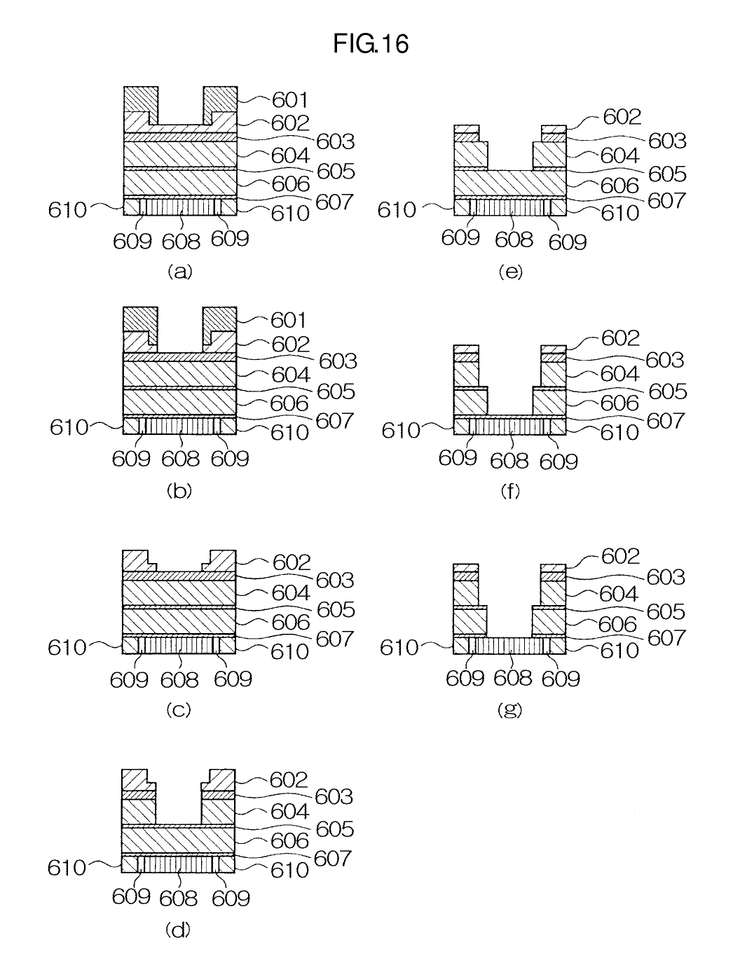

Hereinafter, a case in which a plurality of films of different compositions on a substrate are successively etched by using the plasma processing system 400 of FIG. 9 will be described with reference to FIG. 16. Furthermore, in the present embodiment, a semiconductor wafer (referred to hereinafter as “wafer”) is used as a substrate, and a resist film 601 on which a predetermined pattern is formed, a SiCO film 602 (thickness 150 nm) as a hard mask, a SiCN film 603 (thickness 50 nm), a CF film 604 (thickness 200 nm) with low permittivity, a SiCN film 605 (thickness 50 nm), a CF film 606 (thickness 200 nm) with low permittivity, and a SiCN film 607 (thickness 20 nm) are formed on the wafer as a part of a multi layer wiring structure. A Cu film 608 having a predetermined pattern is formed as the wiring of the bottom layer, and a CF film 610 with low permittivity is formed around the Cu film 608 via a barrier layer 609 (FIG. 16(a)). Furthermore, in the present embodiment, the six layer films including the SiCO film 602, the SiCN film 603, the CF film 604, the SiCN film 605, the CF film 606, and the SiCN film 607 are etched to form a contact hole to the Cu film 608.

First, to etch the SiCO film 602, Ar gas, which is plasma gas, is supplied from the plasma gas source 410 into the processing vessel 51 via the shower plate 61 at a rate of 6.3×10⁻⁶ m/s (380 sccm). Furthermore, Ar gas, C₅F₈ gas, and CF₄ gas, which are processing gases, are supplied from the processing gas source 420 into the processing vessel 51 via the processing gas supplying structure 90 at rates of 3.3×10⁻⁷ m/s (20 sccm), 3.3×10⁻⁷ m/s (20 sccm), and 3.3×10⁻⁷ m/s (20 sccm), respectively. Here, the internal pressure of the processing vessel 51 is maintained at 4.0 Pa (30 mTorr). Then, microwave with 2.45 GHz frequency is radiated from the radial line slot antenna 63 toward the plasma exciting region R1 with power of 2.0 kW. Furthermore, a high frequency of 13.56 MHz is applied to the holding stage 52 by the high frequency power source 54 for bias with power of 300 W. Then, the supplying of plasma gas and processing gases, radiation of microwave, and application of high frequency are performed for 20 seconds to etch 150 nm of the SiCO film 602 by using the resist film 601 as a mask (FIG. 16(b)). Furthermore, exhaust gas generated in the processing vessel 51, during the etching process is exhausted by the exhausting device 102, and PFC gas is collected from the exhaust gas in the exhaust gas processing device 310.

Next, to ash the resist film 601, gases are switched. In other words, Ar gas and O₂ gas are supplied from the shower plate 61 into the processing vessel 51 at a rate of 3.3×10⁻⁶ m/s (200 sccm) and 6.7×10⁻⁶ m/s (400 sccm), respectively. Furthermore, Ar gas is supplied from processing gas supplying structure 90 into the processing vessel 51 at rates of 3.3×10⁻⁷ m/s (20 sccm). Here, the internal pressure of the processing vessel 51 is maintained at 133 Pa (1 Torr). Then, microwave with 2.45 GHz frequency is radiated from the radial line slot antenna 63 toward the plasma exciting region R1 with power of 2.5 kW. Furthermore, a high frequency is not applied to the holding stage 52 by the high frequency power source 54 for bias. Then, the supplying of plasma gases and processing gas, and radiation of microwave are performed for 30 seconds to ash the resist film 601 (FIG. 16(c)). Furthermore, exhaust gas generated in the processing vessel 51, during the ashing process is exhausted to the factory-side exhausting line 323 by the exhausting device 102.

Then, to etch the SiCN film 603, Ar gas, which is plasma gas, is supplied from the shower plate 61 into the processing vessel 51 at a rate of 6.3×10⁻⁶ m/s (380 sccm). Furthermore, Ar gas and CF₄ gas, which are processing gases, are supplied from the processing gas supplying structure 90 into the processing vessel 51 at rates of 3.3×10⁻⁷ m/s (20 sccm) and 1.7×10⁻⁷ m/s (10 sccm), respectively. Here, the internal pressure of the processing vessel 51 is maintained at 6.7 Pa (50 mTorr). Then, the power for microwave with 2.45 GHz frequency radiated from the radial line slot antenna 63 is switched to 1.0 kW. Furthermore, a high frequency of 13.56 MHz is applied to the holding stage 52 with power of 100 W by the high frequency power source 54 for bias. Then, the supplying of plasma gas and processing gases, radiation of microwave, and application of high frequency are performed for 10 seconds to etch 50 nm of the SiCN film 603 by using the SiCO film 602 as a mask. Furthermore, exhaust gas generated in the processing vessel 51 during the etching process is exhausted, and PFC gas is collected from the exhaust gas in the exhaust gas processing device 310.

Then, to etch the CF film 604, the flow of Ar gas, which is plasma gas, supplied from the shower plate 61 into the processing vessel 51 is switched to 3.3×10⁻⁶ m/s (200 sccm). Furthermore, the flows of Ar gas and CF₄ gas, which are processing gases, supplied from the processing gas supplying structure 90 into the processing vessel 51 are set to 3.3×10⁻⁷ m/s (20 sccm) and 3.3×10⁻⁷ m/s (20 sccm), respectively. Here, the internal pressure of the processing vessel 51 is maintained at 3.3 Pa (25 mTorr). Then, the power for microwave with 2.45 GHz frequency radiated from the radial line slot antenna 63 is switched to 1.6 kW. Furthermore, the power for the high frequency power source 54 for bias is switched to 150 W (13.56 MHz). Then, the supplying of plasma gas and processing gases, radiation of microwave, and application of high frequency are performed for 60 seconds to etch the CF film 604.

Furthermore, to over-etch the CF film 604, Ar gas, which is plasma gas, is supplied at a rate of 3.3×10⁻⁶ m/s (200 sccm), whereas the flows of Ar gas and CF₄ gas, which are processing gases, are set to 3.3×10⁻⁷ m/s (20 sccm) and 1.7×10⁻⁷ m/s (10 sccm), respectively. Here, the internal pressure of the processing vessel 51 is maintained at 3.3 Pa (25 mTorr). Then, microwave radiated from the radial line slot antenna 63 is maintained (2.45 GHz with 1.6 kW power), whereas the power for a high frequency of 13.56 MHz applied by the high frequency power source 54 for bias is reduced to 50 W. Then, the supplying of plasma gas and processing gases, radiation of microwave, and application of high frequency are performed for 30 seconds. As a result, the CF film 604 is etched by using the SiCO film 602 as a mask (FIG. 16(d)). Furthermore, exhaust gas generated in the processing vessel 51 during the etching process is exhausted by the exhausting device 102, and PFC gas is collected from the exhaust gas in the exhaust gas processing device 310.

Then, to etch the SiCN film 605, plasma gas supplied from the shower plate 61 into the processing vessel 51 is switched to Xe gas and is supplied at a rate of 6.7×10⁻⁶ m/s (400 sccm). Furthermore, processing gases supplied from the processing gas supplying structure 90 into the processing vessel 51 are switched to Xe gas and C₄F₈ gas and are supplied at rates of 3.3×10⁻⁷ m/s (20 sccm) and 1.7×10⁻⁷ m/s (10 sccm), respectively. Here, the internal pressure of the processing vessel 51 is maintained at 4.7 Pa (35 mTorr). Then, the power for microwave with 2.45 GHz frequency radiated from the radial line slot antenna 63 toward the plasma exciting region R1 is set to 1.0 kW, whereas the power of the high frequency for bias of 13.56 MHz is switched to 80 W. Then, the supplying of plasma gas and processing gases, radiation of microwave, and application of high frequency are performed for 20 seconds to etch the SiCN film 605 by using the CF film 604 as a mask (FIG. 16(e)). Furthermore, exhaust gas generated in the processing vessel 51 during the etching process is exhausted by the exhausting device 102, and PFC gas is collected from the exhaust gas in the exhaust gas processing device 310. Furthermore, exhaust gas exhausted from the exhaust gas processing device 310 is further transferred to the collecting device 430, and Xe gas is collected in the collecting device 430.

Then, to etch the CF film 606, plasma gas is switched to Ar gas and supplied from the shower plate 61 into the processing vessel 51 at a rate of 3.3×10⁻⁶ m/s (200 sccm). Furthermore, processing gases is switched to Ar gas and CF₄ gas and supplied from the processing gas supplying structure 90 into the processing vessel 51 at a rate of 3.3×10⁻⁷ m/s (20 sccm) and 3.3×10⁻⁷ m/s (20 sccm), respectively. Here, the internal pressure of the processing vessel 51 is maintained at 3.3 Pa (25 mTorr). Then, microwave with 2.45 GHz frequency is radiated from the radial line slot antenna 63 toward the plasma exciting region R1 with power switched to 1.6 kW. Furthermore, a high frequency of 13.56 MHz with power switched to 150 W is applied to the holding stage 52 by the high frequency power source 54 for bias. Then, the supplying of plasma gas and processing gases, radiation of microwave, and application of high frequency are performed for 60 seconds.

Furthermore, to over-etch the CF film 606, Ar gas, which is plasma gas, is supplied at a rate of 3.3×10⁻⁶ m/s (200 sccm), whereas Ar gas and CF₄ gas, which are processing gases, are supplied at a rate of 3.3×10⁻⁷ m/s (20 sccm) and 1.7×10⁻⁷ m/s (10 sccm), respectively. Here, the internal pressure of the processing vessel 51 is maintained at 3.3 Pa (25 mTorr). Then, microwave with 2.45 GHz frequency is radiated from the radial line slot antenna 63 with power of 1.6 kW, whereas a high frequency of 13.56 MHz is applied to the holding stage 52 with power of 50 W by the high frequency power source 54 for bias. Then, the supplying of plasma gas and processing gases, radiation of microwave, and application of high frequency are performed for 30 seconds. As a result, the CF film 606 is etched by using the SiCO film 605 as a mask (FIG. 16(f)). Furthermore, exhaust gas generated in the processing vessel 51 during the etching process is exhausted, and PFC gas is collected from the exhaust gas in the exhaust gas processing device 310.

Finally, to etch the SiCN film 607, plasma gas is switched to Xe gas and is supplied from the shower plate 61 into the processing vessel 51 at a rate of 6.7×10⁻⁶ m/s (400 sccm). Furthermore, processing gases are switched to Xe gas and C₄F₈ gas and are supplied from the processing gas supplying structure 90 into the processing vessel 51 at rates of 3.3×10⁻⁷ m/s (20 sccm) and 1.7×10⁻⁷ m/s (10 sccm), respectively. Here, the internal pressure of the processing vessel 51 is maintained at 4.7 Pa (35 mTorr). Then, microwave with 2.45 GHz frequency is radiated from the radial line slot antenna 63 toward the plasma exciting region R1 with power switched to 1.0 kW. Furthermore, the power of the high frequency for bias of 13.56 MHz is switched to 80 W. Then, the supplying of plasma gas and processing gases, radiation of microwave, and application of high frequency are performed for 20 seconds to etch the SiCN film 607 by using the SiCO film 605 as a mask (FIG. 16(g)). Furthermore, exhaust gas generated in the processing vessel 51 during the etching process is exhausted by the exhausting device 102, and PFC gas is collected from the exhaust gas in the exhaust gas processing device 310. Furthermore, exhaust gas exhausted from the exhaust gas processing device 310 is further transferred to the collecting device 430, and Xe gas is collected in the collecting device 430. Accordingly, a contact hole VIA to the Cu film 608 (a bottom wiring layer) is formed.

As described above, a plurality of films of different compositions formed on the substrate W may be successively etched within the single plasma processing device 2 by using the plasma processing system 400 according to the present invention.

### INDUSTRIAL APPLICABILITY

The present invention is effective for a plasma processing system and a plasma processing method for forming or etching a plurality of films of different compositions.

1. A plasma processing system which forms or etches a plurality of films of different compositions, the plasma processing system comprising:
a plasma processing device which forms the plurality of films on a substrate or etches the plurality of films on a substrate by using plasma generated by supplying high frequency;
a gas source which supplies all gases required for forming or etching the plurality of films into the plasma processing device;
a plurality of gas pipes which separately introduce all the gases from the gas source to the plasma processing device;
an exhausting device which exhausts exhaust gas generated in the plasma processing device; and
a control device which selectively supplies gases required for forming or etching each of the plurality of films from the gas source to the plasma processing device via each of the gas pipes.

2. The plasma processing system of claim 1, wherein the control device comprises a flow control device which controls flow of gas supplied into the plasma processing device, and
the flow control device measures the pressure of gas supplied to the plasma processing device and controls flow of the gas to be supplied based on the measured pressure.

3. The plasma processing system of claim 1, wherein the plasma processing device comprises:
a processing vessel which houses and processes a substrate;
a holding unit in the processing vessel, on which a substrate is held;
a high frequency supplying unit, which is formed at a location facing the substrate held on the holding unit and supplies high frequency for generating plasma uniformly with respect to 2 dimensions into the inside of the processing vessel;
a plate-shaped structure, which is formed between the high frequency supplying unit and the holding unit and divides a region between the high frequency supplying unit and the holding unit into a region at the side of the high frequency supplying unit and a region at the side of the holding unit;
a plasma gas source, which is formed at a location below the high frequency supplying unit to face the top surface of the structure and supplies gas for exciting plasma uniformly with respect to 2 dimensions to the region at the side of the high frequency supplying unit; and
a gas supplying path which supplies gas from the plurality of gas pipes to the plasma gas source and the structure, and
a plurality of processing gas supplying holes which supply processing gas for the film-formation or film-etching uniformly with respect to 2 dimensions to the region at the side of the holding unit and a plurality of openings via which plasma generated uniformly with respect to 2 dimensions in the region at the side of the high frequency supplying unit passes toward the region at the side of the holding unit are formed in the structure.

4. The plasma processing system of claim 3, wherein a gas protection film containing no water molecules and no pinhole void and having corrosion-resistance with respect to plasma gas and processing gas is formed on the inner surface of the processing vessel.

5. The plasma processing system of claim 4, wherein the gas protection film is an Al₂O₃ film.

6. The plasma processing system of claim 3, wherein the inner surface of the processing vessel is heated to a temperature between 100° C. and 200° C.

7. The plasma processing system of claim 3, wherein the frequency of high frequency supplied from the high frequency supplying unit is 915 MHz, 2.45 GHz, or 450 MHz.

8. The plasma processing system of claim 1, wherein the internal pressure of the exhausting device continuously increase from the side of the side of entrance to the exit.

9. The plasma processing system of claim 1, wherein the ratio between the pressure of exhaust gas at the side of the entrance of the exhausting device and the pressure of exhaust gas at the side of the exit of the exhausting device is above 10,000, and
the pressure of exhaust gas at the side of the exit of the exhausting device is from 0.4 kPa to 4.0 kPa.

10. The plasma processing system of claim 1, wherein the exhausting device comprises a single stage vacuum pump or serially connected double stage vacuum pumps,
the vacuum pump or pumps in each of the stages are arranged singularly or arranged plurally in parallel, and
flow of exhaust gas at the side of the exit of the exhausting device is viscous flow.

11. The plasma processing system of claim 10, wherein the vacuum pump of the exhausting device comprises a screw vacuum pump,
the screw vacuum pump comprises:
interlocked rotors of which the angles of spiral of saw-toothed wheels are continuously changed; and
a casing which houses the interlocked rotors, and
the volumes of an operation chamber formed by the interlocked rotors and the casing is continuously reduced from the suction side to the ejection side of exhaust gas.

12. The plasma processing system of claim 10, wherein an exhaust gas protection film containing no water molecules and no pinhole void and having corrosion-resistance with respect to exhaust gas is formed on the inner surface of the vacuum pump of the exhausting device.

13. The plasma processing system of claim 12, wherein the exhaust gas protection film is an Al₂O₃ film or a Y₂O₃ film.

14. The plasma processing system of claim 10, wherein the inner surface of the vacuum pump of the exhausting device is heated to a temperature between 100° C. and 200° C.

15. The plasma processing system of claim 1, wherein, a plurality of exhaust gas processing devices which process different types of exhaust gases generated in the plasma processing device, another exhausting device formed at the side of the exits of the plurality of exhaust gas processing devices, a plurality of first valves which control inflow of exhaust gas from the exhausting device to each of the exhaust gas processing devices, and a plurality of second valves which control inflow of processed exhaust gas from each of the exhaust gas processing device to the other exhausting device are formed at the downstream side of the exhausting device, and
the plasma processing device, the exhausting device, the first valves, the exhaust gas processing devices, the second valves, and the other exhausting device are connected via exhausting pipes in the order stated.

16. The plasma processing system of claim 15, wherein the first valves are capable of operating with respect to exhaust gas at a temperature between 100° C. and 200° C.

17. The plasma processing system of claim 15, wherein a PFA film or a fluorocarbon film is formed on the surfaces of diaphragms of the first valves.

18. The plasma processing system of claim 15, wherein an exhaust gas protection film containing no water molecules and no pinhole void and having corrosion-resistance with respect to exhaust gas is formed on the inner surfaces of each of the first valves and the exhausting pipes.

19. The plasma processing system of claim 18, wherein the exhaust gas protection film is an Al₂O₃ film or a Y₂O₃ film.

20. The plasma processing system of claim 15, wherein the inner surfaces of each of the first valves, the exhausting pipes which transfer exhaust gas from the exhausting device to the first valves, and the exhausting pipes which transfer exhaust gas from the first valves to the exhaust gas processing devices are heated to a temperature between 100° C. and 200° C.

21. The plasma processing system of claim 15, wherein the other exhausting device comprises a single stage vacuum pump or serially connected double stage vacuum pumps.

22. The plasma processing device of claim 15, wherein a collecting device for Kr and/or Xe and a third valve for selectively supplying exhaust gas containing Kr and/or Xe to the collecting device are formed at the downstream side of the other exhausting device.

23. A plasma processing method which successively forms or etches a plurality of films of different compositions, the plasma processing method for successively performing:
a first process for selectively supplying gas required for forming or etching a first film among the plurality of films into a processing vessel, which houses a substrate, as controlling flow of the gas and generating plasma 2-dimensionally and uniformly by 2-dimensionally and uniformly supplying high frequency into the processing vessel, so as to form or etch the first film by using the plasma; and
a second process for selectively supplying gas required for forming or etching a second film among the plurality of films into the processing vessel and generating the plasma, so as to form or etch the second film by using the plasma.

24. The plasma processing method of claim 23, wherein, exhaust gas is exhausted from the processing vessel and is processed in the first process or the second process.

25. The plasma processing method of claim 23, wherein the second process is performed immediately after the first process without interposing any other process therebetween.

26. The plasma processing method of claim 23, wherein, after the first process, the second process is performed after an inert gas is supplied into the processing vessel and the processing vessel is exhausted.

27. A method of manufacturing an electronic device, the method comprising a process of successively forming or successively etching a plurality of films of different compositions based on the plasma processing method of claim 23.

28. The method of claim 27, wherein the electronic device is a semiconductor device, a flat panel display device, or a solar battery.
